(19) United States
(12) Patent Application Publication
(10) Pub. No.: US 2014/0299873 A1
(43) Pub. Date: Oct. 9, 2014

(54) SINGLE-CRYSTAL OXIDE SEMICONDUCTOR, THIN FILM, OXIDE STACK, AND FORMATION METHOD THEREOF

(71) Applicant: Semiconductor Energy Laboratory Co., Ltd., Atsugi-shi (JP)

(72) Inventor: Shunpei YAMAZAKI, Setagaya (JP)

(73) Assignee: Semiconductor Energy Laboratory Co., Ltd.

(21) Appl. No.: 14/230,566

(22) Filed: Mar. 31, 2014

(30) Foreign Application Priority Data
Apr. 5, 2013 (JP) 2013-079300

(51) Int. Cl. H01L 21/02; H01L 29/26

(52) U.S. Cl. CPC H01L 21/02565; H01L 21/02587; H01L 29/26
USPC 257/43; 438/104

(57) ABSTRACT

To provide a metal oxide film including a single-crystal region. An oxide semiconductor film including indium and zinc is formed by a sputtering method by using a c-axis-aligned polycrystalline sputtering target at a substrate temperature of 200° C. or higher and 500° C. or lower. In this case, the oxide semiconductor film is formed over a c-axis-aligned zinc oxide film with a thickness of 0.1 nm or more and 5 nm or less. Consequently, it is possible to form an island-shaped single crystal with an average thickness of 0.5 μm or less, preferably 5 nm or more and 0.1 μm or less and an area of 5 μm² or more, preferably 1000 μm² or more. The oxide semiconductor film is a thin film extremely close to a single crystal which includes such an island-shaped single crystal at 80% or more, preferably 95% or more in the film.

### BACKGROUND OF THE INVENTION

1. Field of the Invention

The present invention relates to a metal oxide film.

In this specification, a semiconductor device generally refers to a device which can function by utilizing semiconductor characteristics; an electro-optical device, a semiconductor circuit, and an electronic device are all included in the category of the semiconductor device.

2. Description of the Related Art

Thin films of an insulating metal oxide, a conductive metal oxide, and a semiconductor metal oxide (also referred to as an oxide semiconductor) are used for a variety of products such as semiconductor devices.

A sputtering method has a variety of advantages such that a film having strong attachment to a substrate can be formed, film formation can be performed without changing the most of the composition of a sputtering target, and film thickness can be controlled with high accuracy only by controlling time. For example, it is widely used as a method for forming an oxide semiconductor including indium, gallium, and zinc (Patent Document 1). The oxide semiconductor film has attracted attention because of its properties such as carrier mobility higher than that of an amorphous silicon thin film and has been actively researched.

In a transistor using an oxide semiconductor film including indium, gallium, and zinc, although transistor characteristics can be obtained relatively easily, physical properties are unstable; thus, it has been difficult to ensure reliability of the transistor.

However, a result of recent research and development shows that using a crystalline oxide semiconductor film increases reliability of a transistor (Patent Documents 2 to 4 and Non-Patent Document 1).

There is no limitation to an oxide semiconductor film, and if a crystalline metal oxide film can be formed by a sputtering method, the film is expected to be a conductive film having high conductivity, an insulating film having high withstand voltage, or the like, which enables a variety of applications of them.

### REFERENCE

### Patent Document

[Patent Document 1] PCT International Publication No. WO 2005/088726

### [Patent Document 2] United States Patent Application Publication No. 2011/0147739

### [Patent Document 3] United States Patent Application Publication No. 2012/0064664

### [Patent Document 4] United States Patent Application Publication No. 2012/0312681

### Non-Patent Document

### [Non-Patent Document 1] Shunpei Yamazaki, Jun Koyama, Yoshitaka Yamamoto, and Kenji Okamoto, “Research, Development, and Application of Crystalline Oxide Semiconductor”, SID 2012 DIGEST, pp. 183-186

### SUMMARY OF THE INVENTION

An object of one embodiment of the present invention is to provide a crystalline metal oxide film.

In order to achieve the above object, in one embodiment of the present invention, the metal oxide film is formed by a sputtering method using a c-axis-aligned polycrystalline sputtering target of metal oxide at a substrate temperature higher than or equal to 200° C. and lower than or equal to 500° C. In that case, the metal oxide film is formed over a film of a c-axis-aligned crystalline oxide (e.g., zinc oxide) with a thickness greater than or equal to 0.1 nm and less than or equal to 5 nm, preferably greater than or equal to 1 nm and less than or equal to 3 nm. The metal oxide film formed in such a manner has quite excellent crystallinity.

In the above, the c-axis-aligned crystalline oxide may be a hexagonal crystal.

In the above, the silicon content and the carbon content each may be lower than 1×10¹⁸ atoms/cm³.

In the above, the metal oxide is an In-M-Zn oxide (M is one or more of metal elements and includes at least one of aluminum, tin, gallium, yttrium, zirconium, lanthanum, cerium, and neodymium), and the proportion of zinc may be higher than that of M in an atomic ratio. Further, the proportion of zinc may be higher than that of indium in an atomic ratio.

Further, in a polycrystalline In-M-Zn oxide sputtering target used for forming the metal oxide, the proportion of zinc may be higher than that of M in an atomic ratio. Furthermore, the proportion of zinc may be higher than that of indium in an atomic ratio. Note that the proportion of zinc in the sputtering target may be higher than that in the metal oxide in an atomic ratio.

The In-M-Zn oxide used to manufacture the sputtering target may be a homologous compound. Here, the proportion of zinc may be higher than that of M in an atomic ratio in the In-M-Zn oxide. Further, the proportion of zinc may be higher than that of indium in an atomic ratio.

One embodiment of the present invention is a single-crystal thin film or an island-shaped single crystal (or a single-crystal-like object) including an In-M-Zn oxide (M is one or more of metal elements and includes at least one of aluminum, tin, gallium, yttrium, zirconium, lanthanum, cerium, and neodymium) formed over an amorphous surface, the average thickness thereof is less than or equal to 0.5 μm, preferably greater than or equal to 5 nm and less than or equal to 0.1 μm, and the area thereof is greater than or equal to 5 μm², preferably greater than or equal to 1000 μm². Alternatively, a thin film extremely close to a single crystal or a thin film equivalent to a single crystal which contains such an island-shaped crystal at a proportion of higher than or equal to 80%, preferably higher than or equal to 95% in the film. Note that crystal defects, stacking defects, dislocation, or the like may be contained.

A zinc oxide film may be included between the above In-M-Zn oxide and a substrate.

The amorphous surface may have an insulating property. Note that the amorphous surface may be uneven, in which case a zinc oxide film, the above single-crystal thin film, or an island-shaped single crystal (or a single-crystal-like object) is affected by the uneven surface and thus, atomic arrangement along the uneven surface is obtained in some cases.

According to one embodiment of the present invention, a crystalline metal oxide film can be provided.

### BRIEF DESCRIPTION OF THE DRAWINGS

In the accompanying drawings:

FIGS. 1A to 1C illustrate an example of a sputtering target;

FIG. 2 is a flow chart showing an example of a method for manufacturing a sputtering target;

FIGS. 3A to 3F illustrate an example of a method for manufacturing a sputtering target;

FIGS. 4A, 4B1, 4B2, and 4C are schematic views illustrating a situation where a spattered particle is separated from a sputtering target;

FIGS. 5A and 5B are schematic views illustrating a situation where a sputtered particle reaches a deposition surface and is deposited;

FIGS. 6A to 6C are schematic diagrams illustrating a method for manufacturing a metal oxide;

FIGS. 7A and 7B illustrate an example of a crystal structure of an In—Ga—Zn oxide;

FIG. 8 is a top view of a deposition apparatus;

FIG. 9 is a cross-sectional view of a deposition apparatus;

FIGS. 10A1, 10A2, 10B1, and 10B2 are diagrams illustrating plasma discharge in a sputtering method using a DC source and an AC source;

FIGS. 11A to 11C are a top view and cross-sectional views illustrating one embodiment of a transistor;

FIGS. 12A to 12D are cross-sectional views illustrating one embodiment of a method for manufacturing a transistor;

FIGS. 13A to 13C are a top view and cross-sectional views illustrating one embodiment of a transistor;

FIGS. 14A to 14C are a top view and cross-sectional views illustrating one embodiment of a semiconductor device;

FIGS. 15A to 15D are cross-sectional views illustrating one embodiment of a method for manufacturing a semiconductor device;

FIGS. 16A to 16C are cross-sectional views illustrating one embodiment of a method for manufacturing a semiconductor device;

FIGS. 17A to 17C are perspective views illustrating one embodiment of a method for manufacturing a FIN-type transistor;

FIGS. 18A and 18B are perspective views illustrating one embodiment of a method for manufacturing a FIN-type transistor;

FIGS. 19A and 19B are conceptual diagrams of an active matrix light-emitting device;

FIG. 20 is a conceptual diagram of an active matrix light-emitting device; and

FIGS. 21A, 21B1, 21B2, 21C, and 21D each illustrate an electronic device.

### DETAILED DESCRIPTION OF THE INVENTION

Hereinafter, embodiments of the present invention will be described in detail with reference to the accompanying drawings. However, the present invention is not limited to the description below, and it is easily understood by those skilled in the art that modes and details thereof can be modified in various ways. Therefore, the present invention is not construed as being limited to description of the embodiments. In describing structures of the present invention with reference to the drawings, the same reference numerals are used in common for the same portions in different drawings. Note that the same hatch pattern is applied to similar parts, and the similar parts are not especially denoted by reference numerals in some cases.

Note that the ordinal numbers such as “first” and “second” in this specification and the like are used for convenience and do not denote the order of steps or the stacking order of layers. Therefore, for example, description can be made even when “first” is replaced with “second” or “third”, as appropriate. In addition, the ordinal numbers in this specification do not correspond to the ordinal numbers which specify one embodiment of the present invention in some cases.

In this specification and the like, the size of a crystal region means the size of a crystal region which appears on a flat plane of a metal oxide. The size of a crystal region which appears on a flat plane of a metal oxide can be measured using a backscattered electron image obtained by an optical microscope or a scanning electron microscope, a transmission electron microscope image, or the like.

### Embodiment 1

In this embodiment, a target including a c-axis-aligned polycrystalline metal oxide and a deposition method using the target are described. Note that as is apparent from that the metal oxide is c-axis-aligned, the crystal structure of the metal oxide is a hexagonal crystal structure or the like, not a cubic crystal structure. In this specification, trigonal and rhombohedral crystal systems are included in a hexagonal crystal system.

Note that “being c-axis-aligned to a plane” means that an angle between the c-axis of each of 80% or more of crystals and a normal of the plane is greater than or equal to −15° and less than 15°. “The angle is 0° ” means that the case where the c-axis thereof is parallel to a normal of the plane.

<Target>

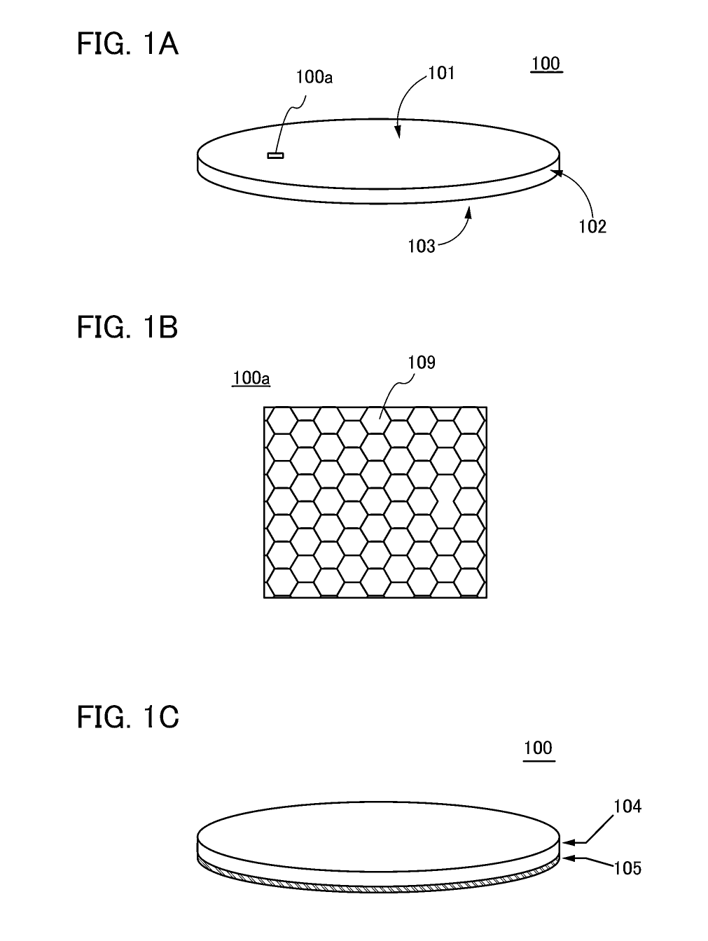

FIG. 1A illustrates a target 100 including a c-axis-aligned polycrystalline metal oxide of one embodiment of the present invention, and FIG. 1B is an enlarged schematic view of part of the target 100. As illustrated in FIG. 1A, the target 100 has a surface on which sputtering is mainly performed (so-called a sputtering surface 101), a side surface 102, and a back surface 103. Here, the sputtering surface 101 faces plasma in the sputtering. The back surface 103 is attached to a backing plate.

Although the target illustrated in FIG. 1A has a circular shape, another shape may be employed.

As illustrated in FIG. 1B, the target 100 includes a plurality of crystal grains 109.

Specifically, the average grain size of the crystal grains is preferably greater than or equal to 0.01 μm and less than or equal to 3.0 μm, more preferably greater than or equal to 0.1 μm and less than or equal to 2.0 μm.

Further, the standard deviation of the grain sizes of the crystal grains is preferably less than or equal to the average grain size of the crystal grains, more preferably less than or equal to ½ of, further more preferably less than or equal to ⅕ of the average grain size of the crystal grains. Further, the grain sizes of 68% of the crystal grains are preferably two times or less, more preferably 0.5 to 1.5 times, further more preferably 0.8 to 1.2 times as large as the average grain size of the crystal grains.

The composition of the metal oxide included in the target 100 can be determined as appropriate depending on a desired metal oxide film. The metal oxide film preferably contains at least indium, and more preferably contains both indium and zinc. Further, in addition to these, at least one of gallium, tin, hafnium, and aluminum is preferably contained because variation in electrical characteristics can be reduced.

In the case where the target contains indium, zinc, and another metal element (e.g., aluminum, tin, gallium, yttrium, zirconium, lanthanum, cerium, or neodymium), the proportion of zinc is preferably larger than those of the other metal elements in an atomic ratio. A metal element refers to all elements other than a rare gas element, hydrogen, boron, carbon, nitrogen, Group 16 elements (e.g., oxygen), Group 17 elements (e.g., fluorine), silicon, phosphorus, germanium, arsenic, and antimony.

For example, the composition (atomic ratio) of indium, gallium, and zinc of the target is indium:gallium:zinc=1:1:1, indium:gallium:zinc=5:5:6, indium:gallium:zinc=1:3:4, indium:gallium:zinc=1:3:5, indium:gallium:zinc=1:3:6, indium:gallium:zinc=1:3:7, indium:gallium:zinc=1:3:8, indium:gallium:zinc=1:3:9, indium:gallium:zinc=1:3:10, indium:gallium:zinc=1:6:7, indium:gallium:zinc=1:6:8, indium:gallium:zinc=1:6:9, or indium:gallium:zinc=1:6:10.

In the case where an oxide semiconductor film is formed using the above target, when an impurity is included in a target, electrical characteristics of a transistor including the oxide semiconductor film formed using the target might be adversely affected. Therefore, it is preferable that the impurity concentration in the target be reduced. As examples of the impurity in the target, silicon, carbon, nitrogen, boron, arsenic, another metal element involuntarily mixed, or the like can be given. In particular, it is revealed that silicon and carbon form impurity states in an oxide semiconductor film and make the oxide semiconductor film n-type, or serve as trap states. Thus, the silicon content and the carbon content in the target are each preferably lower than 1×10¹⁸ atoms/cm³, more preferably lower than 3×10¹⁷ atoms/cm³.

Note that the target 100 may include an auxiliary material. The target 100 illustrated in FIG. 1C shows an example where a metal oxide layer 104 used for the deposition is formed over an auxiliary oxide layer 105. That is, the auxiliary oxide layer 105 exists on the back surface of the target 100. Here, the auxiliary oxide layer 105 is used to increase the degree of c-axis alignment of the metal oxide layer 104 used for the deposition.

For example, single-crystal zinc oxide or a sintered body of c-axis-aligned zinc oxide is used for the auxiliary oxide layer 105, and as the metal oxide, In—Ga—Zn oxide powder or a material obtained in such a manner that the powder is molded by being pressed is placed over and in close contact with the auxiliary oxide layer 105 and is heated by being pressed, so that a sintered body of In—Ga—Zn oxide that is c-axis-aligned polycrystal (the metal oxide layer 104 used for the deposition) can be obtained.

### <Method for Manufacturing Target>

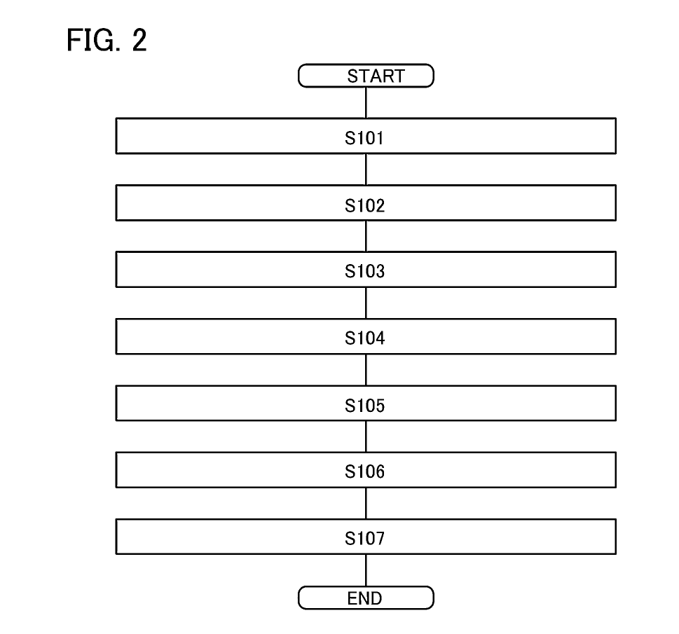

An example of a method for manufacturing the target 100 including a polycrystalline metal oxide is described below with reference to FIG. 2. Here, although description is made using a target including indium, gallium, and zinc as an example, a target having another composition can be manufactured in a similar manner by changing a raw material.

First, a metal oxide which is a raw material is synthesized (Step S101). In the case where a target including indium oxide, gallium oxide, and zinc oxide is manufactured, the raw material is an indium oxide powder, a gallium oxide powder, and a zinc oxide powder. In such a case, each of the raw material powders is required to have sufficiently high purity, and for example, the purity of each of the raw material powders is 99.9999% or more.

As a synthesis method of the raw material, a known method can be employed. For example, as one of synthesis methods of an metal oxide powder, there is a method in which a metal hydroxide is generated and precipitated by mixing an alkaline solution and a metal salt such as a nitrate or a sulfate to be naturalized, precipitation of the metal hydroxide is collected by filtration or the like, and then the metal hydroxide is baked to obtain a metal oxide.

Next, the raw material obtained in Step S101 is ground (Step S102). At this time, the size of the grounded metal oxide powder preferably becomes less than or equal to 1 μm, more preferably becomes less than or equal to 0.17 μm, further more preferably becomes less than or equal to 0.03 μm.

For the grinding, a mill machine or cracking machine such as a ball mill or a bead mill, a jet mill, a vibration filter, ultrasonic waves, or the like can be used. In the case of using a bead mill, the metal oxide powder can be grounded to several tens of nanometers. In the case of using a jet mill, entry of an unintended element can be suppressed. Note that this grinding step in Step S102 may be performed between collecting precipitation of a metal hydroxide in Step S101 and baking the metal hydroxide.

Note that classification may be performed on the metal oxide powder obtained in Step S102 once or a plurality of times. For example, second classification is preferably performed on the metal oxide powder on which first classification has been performed.

Coarse grains are removed by one of the first classification and the second classification and fine grains are removed by the other, so that the metal oxide powder with uniform grain size can be obtained. Specifically, the standard deviation of the grain sizes of the crystal grains is preferably less than or equal to the average grain size of the crystal grains, more preferably less than or equal to ½ of, further more preferably less than or equal to ⅕ of the average grain size of the crystal grains.

As a classification method, any of a dry method, a wet method, and a screening method may be used. The screening method enables classification of even fine particles with less than or equal to 1 μm with high accuracy and has a cost advantage. Classification using a centrifugal precipitator or a hydraulic cyclone, which is a wet classification, has advantages of having a high processing ability and a good classification performance.

Next, the obtained metal oxide powders are prepared and mixed (Step S103). Here, the indium oxide powder, the gallium oxide powder, and the zinc oxide powder are prepared to obtain a desired composition and then mixed with a ball mill or the like.

Next, the prepared and mixed powder is baked as it is powder (Step S104). The baking is performed at a temperature higher than or equal to 300° C. and lower than 1600° C., for example. When the baking temperature is lower than 300° C., there is a concern that crystallization from crystals of indium oxide, gallium oxide, and zinc oxide which are the raw material to an indium-gallium-zinc oxide do not progress sufficiently. Further, as the baking temperature is higher, crystal grows in the a-axis direction and the b-axis direction, and a flat-plate-like crystal can be clearly observed; thus, as described later, the baking at high temperature is advantageous for making the sputtering surface of the target c-axis-aligned. However, when the baking temperature is higher than or equal to 1600° C., the metal composition might differ from a desired composition. In particular, since zinc is easily vaporized, the proportion of zinc might be decreased from the original one.

Next, the baked powder is ground (Step S105). For example, in the case of an In—Ga—Zn oxide, its a-b plane is easily cleaved; thus, a powder-like crystal having a flat-plate-like shape can be obtained.

Next, the powder-like crystal obtained in Step S105 is shaped into a target by applying pressure and sintered (Step S106). As described above, since the crystal has a flat-plate-like shape, by applying pressure in one direction, crystals are easily aligned to be perpendicular to the pressure direction. Therefore, by applying pressure parallel to a normal of a sputtering surface (or back surface) when the crystal is used for a target, the powder can be compacted (including molded) so that the c-axis thereof is parallel to the normal of the sputtering surface (or back surface).

Examples of methods for forming the compact include a metal molding method, a cold isostatic pressing method, and the like. Note that in the compacting process, a compacting aid such as polyvinyl alcohol, methyl cellulose, polywax, or an oleic acid may be used as appropriate.

The sintering is performed at a temperature of, for example, higher than or equal to 1200° C. and lower than 1600° C., preferably higher than or equal to 1300° C. and lower than 1500° C. When the sintering temperature is lower than 1200° C., there is a concern that the sintering does not progress sufficiently. Further, when the sintering temperature is higher than or equal to 1600° C., the metal composition might differ from a desired composition. As described above, since zinc is easily vaporized, the proportion of zinc of the surface of the target is lower than that of the inside of the target in an atomic ratio in some cases.

Note that a sputtering target can be manufactured by performing the compacting step and the sintering step at the same time. Examples of such compacting methods include hot pressing, hot isostatic pressing, and the like. Hot press sintering is preferably performed because a sputtering target which has a small number of air gaps and high density and is c-axis-aligned is easily manufactured.

Then, the sintered compact may be subjected to heat treatment in a reducing atmosphere of hydrogen, methane, carbon monoxide, or the like or in an inert gas atmosphere of nitrogen, a rare gas, or the like. Accordingly, resistance variation of the sintered compact can be reduced.

Next, the sintered compact obtained in Step S106 is subjected to finishing treatment (Step S107). As the finishing treatment, cutting, surface grinding, bonding to a backing plate, or the like can be performed. In particular, it is preferable that after the cutting, the sintered compact be subjected to mirror finishing to a surface roughness (Ra) of 5 μm or less, preferably 2 μm or less. Examples of mirror finishing methods include mechanical polishing, chemical polishing, CMP, and the like.

Through the above process, the target 100 including a polycrystalline metal oxide including the c-axis-aligned sputtering surface can be manufactured. Note that the surface of the target 100 and the inside of the target 100 have different degrees of alignment, and for example, in processing by hot press, the surface has a higher degree of alignment than the inside. The target including a c-axis-aligned polycrystalline metal oxide may include at least a c-axis-aligned surface.

The above is the method for manufacturing a target formed of only a polycrystalline metal oxide layer. A method for manufacturing a target including the auxiliary oxide layer 105 which is illustrated in FIG. 1C is described below. In this case, the auxiliary oxide layer is a single-crystal sintered compact or a c-axis-aligned polycrystalline sintered body, and the powder-like crystal pf a polycrystalline oxide obtained in Step S105 is placed over the auxiliary oxide layer and is compacted by being pressed. After that, a c-axis-aligned sintered compact can be obtained by the sintering and is processed to obtain the target.

### <Method for Forming Metal Oxide Film>

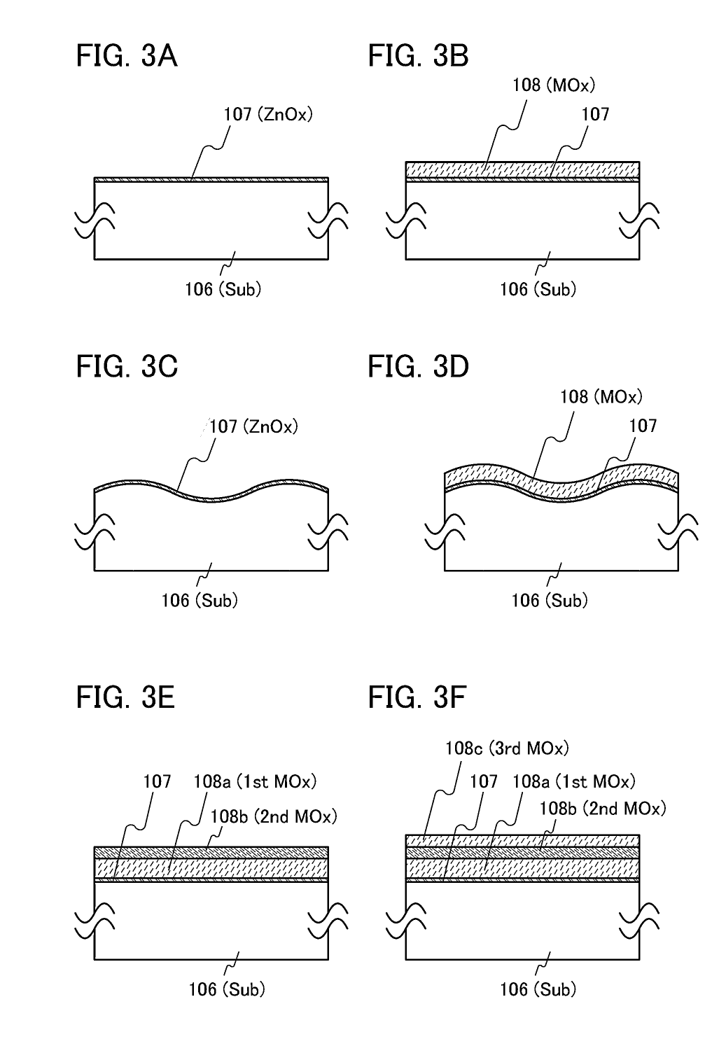

An example of a method for forming a metal oxide film over an amorphous surface by using the above c-axis-aligned target is described below with reference to FIGS. 3A and 3B.

First, a c-axis-aligned zinc oxide film 107 is formed over a substrate 106 having an amorphous surface to a thickness of greater than or equal to 0.1 nm and less than or equal to 5 nm, preferably greater than or equal to 1 nm and less than or equal to 3 nm (see FIG. 3A). Examples of the substrate 106 having the amorphous surface include a variety of glass substrates, a variety of plastic substrates, a variety of metal substrates, and a variety of semiconductor substrates (e.g., silicon wafers) each of which is coated with silicon oxide, silicon nitride, silicon oxynitride, aluminum oxide, aluminum nitride, or the like; however, the substrate 106 is not limited thereto. The amorphous surface may have an insulating property.

The zinc oxide film 107 can be manufactured by a sputtering method. Further, the zinc oxide film 107 can contain one or more of metal elements other than zinc at a proportion of 10% or less of zinc in the film. In other words, zinc among metal elements included in the zinc oxide film 107 is contained at a proportion of 90% or higher in the film.

The zinc oxide film 107 may be heated during formation. Further, the zinc oxide film 107 may be crystallized by heat treatment after the formation. In any case, the c-axis-aligned zinc oxide film 107 is formed. For example, the zinc oxide film 107 which is sufficiently c-axis-aligned can be obtained under the following conditions: a mixed gas of argon and oxygen is used as the sputtering gas, the flow ratio thereof is argon:oxygen=20 sccm:10 sccm, the pressure is 0.4 Pa, and the temperature of the substrate 106 is 200° C.

After that, the metal oxide film 108 with a thickness less than or equal to 0.5 μm, preferably greater than or equal to 5 nm and less than or equal to 0.1 μm is formed over the substrate 106 by the sputtering method using the above metal oxide target. At this time, the temperature of the substrate 106 is higher than or equal to 200° C. and lower than or equal to 500° C.

When the metal oxide film 108 is formed, the total of partial pressures of hydrogen, a hydrogen compound, water vapor, and the like in a deposition chamber (reaction container) is lower than or equal to 30 ppm, preferably lower than or equal to 30 ppb. In order to minimize residual gases such as oxygen and water in the chamber, the ultimate pressure is lowered to an ultra-high vacuum (UHV) region of higher than or equal to 1×10⁻⁵ Pa and lower than or equal to 1×10⁻⁸ Pa. After that, a gas used for the deposition (sputtering gas) is introduced. As the sputtering gas, a high-purity gas with a dew point of lower than or equal to −60° C., preferably lower than or equal to −100° C.

In addition, it is preferable that the metal oxide film 108 be deposited in an oxidation atmosphere or. Note that an oxidation atmosphere refers to an atmosphere containing an oxidation gas. Oxidation gas is oxygen, ozone, nitrous oxide, or the like, and it is preferable that the oxidation gas do not contain water, hydrogen, and the like. For example, the purity of oxygen, ozone, or nitrous oxide is greater than or equal to 8N (99.999999%), preferably greater than or equal to 9N (99.9999999%).

The oxidation atmosphere may contain a mixed gas of an oxidation gas and an inert gas. In that case, the atmosphere contains an oxidation gas at a concentration of at least higher than or equal to 10 ppm. Note that the inert atmosphere refers to an atmosphere which contains an inert gas such as nitrogen or a rare gas or an atmosphere which does not contain a reactive gas such as an oxidation gas. Specifically, in an inert atmosphere, the concentration of a reactive gas such as an oxidation gas is lower than 10 ppm. Note that the pressure of each of the oxidation atmosphere and the inert atmosphere may be a reduced pressure that is lower than or equal to 100 Pa, lower than or equal to 10 Pa, or lower than or equal to 1 Pa.

Note that in this specification, an interface between the zinc oxide film 107 and the metal oxide film 108 is clear for convenience; however, although the metal oxide film 108 is deposited over the zinc oxide film 107, there is the case where the interface thereof is not clear, the case where the interface disappears, or the case where the zinc oxide film 107 disappears. In such a case, the zinc oxide film 107 cannot be found after the metal oxide film 108 is formed.

However, a metal oxide film having a crystal state and a thickness of 5 nm or more which is almost in contact with the amorphous surface (interface) can be easily found. Note that in the case where the metal oxide film is formed directly on the amorphous surface, order (crystallinity) with a length of 2 nm or longer cannot be found in portions with approximately 5 nm from the amorphous surface (interface) of the metal oxide film.

Note that for example, in the case where the substrate 106 has an uneven (curved) surface as illustrated in FIG. 3C, the zinc oxide film 107 is also formed along the uneven surface. After that, when the metal oxide film 108 is deposited, the metal oxide film 108 has crystallinity as affected by the crystallinity of the curved zinc oxide film 107 as illustrated in FIG. 3D.

Here, deposition mechanism of the metal oxide film 108 is described.

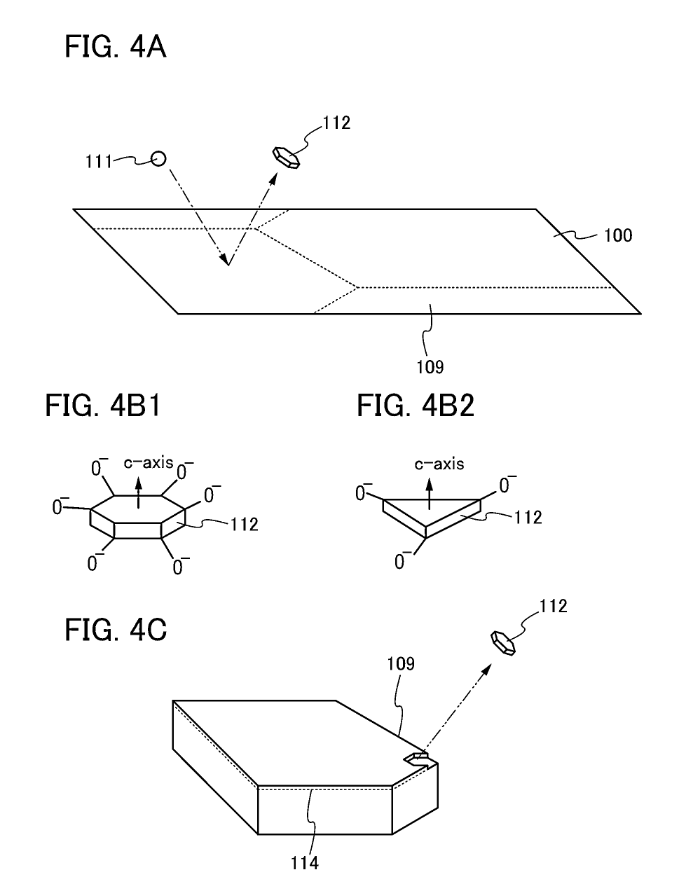

FIG. 4A is a schematic view illustrating a situation where an ion 111 collides with the target 100 and a sputtered particle 112 is generated. The target 100 in FIG. 4A is the target including the polycrystalline metal oxide illustrated in FIGS. 1A to 1C and includes the crystal grain 109. The sputtered particle 112 is varied depending on the composition of the target, and here includes a plurality of atoms included in the crystal grain 109 and has crystallinity.

As the ion 111, an oxygen ion can be used. Further, in addition to the oxygen ion, an argon ion may be used. Another rare gas ion may be used. When an oxygen ion is used as the ion 111, plasma damage at the deposition can be reduced. Thus, when the ion 111 collides with the surface of the target 100, a lowering in crystallinity of the target 100 can be suppressed.

FIG. 4C illustrates a detailed situation where the sputtered particle 112 is separated from the crystal grain 109. According to FIG. 4C, the crystal grain 109 has a cleavage plane 114 parallel to a sputtering surface of the target 100. The crystal grain 109 has a portion where an interatomic bond is weak. At the time of collision of the ion 111 with the crystal grain 109, an interatomic bond of the portion where an interatomic bond is weak is cut. Accordingly, the sputtered particle 112 is separated in a flat-plate form by being cut out along the cleavage plane 114 and the portion where an interatomic bond is weak. The sputtered particle 112 having such a flat-plate-like shape is also referred to as a pellet.

Note that the sputtered particle 112 may have a hexagonal prism shape in which the cleavage plane 114 is a flat plane parallel to an a-b plane. In such a case, a direction perpendicular to a hexagonal plane is a c-axis direction of the crystal (see FIG. 4B1). The sputtered particle 112 may have a triangular prism shape in which the cleavage plane is a flat plane parallel to an a-b plane. In such a case, a direction perpendicular to a triangular plane is a c-axis direction of the crystal (see FIG. 4B2). Alternatively, the sputtered particle 112 may have a polygonal prism shape different from the above.

It is preferable that the sputtered particles 112 be positively or negatively charged. There is no particular limitation on a timing of when the sputtered particle 112 is charged, but it is preferably charged by receiving a charge when the ion 111 collides. Alternatively, in the case where plasma is generated, the sputtered particle 112 is preferably exposed to plasma to be charged. Further alternatively, the ion 111 is preferably bonded to a surface of the sputtered particle 112, whereby the sputtered particle 112 is charged. Note that in some cases, part or all of the vertexes of the sputtered particle 112 are bonded to oxygen ions to be negatively charged.

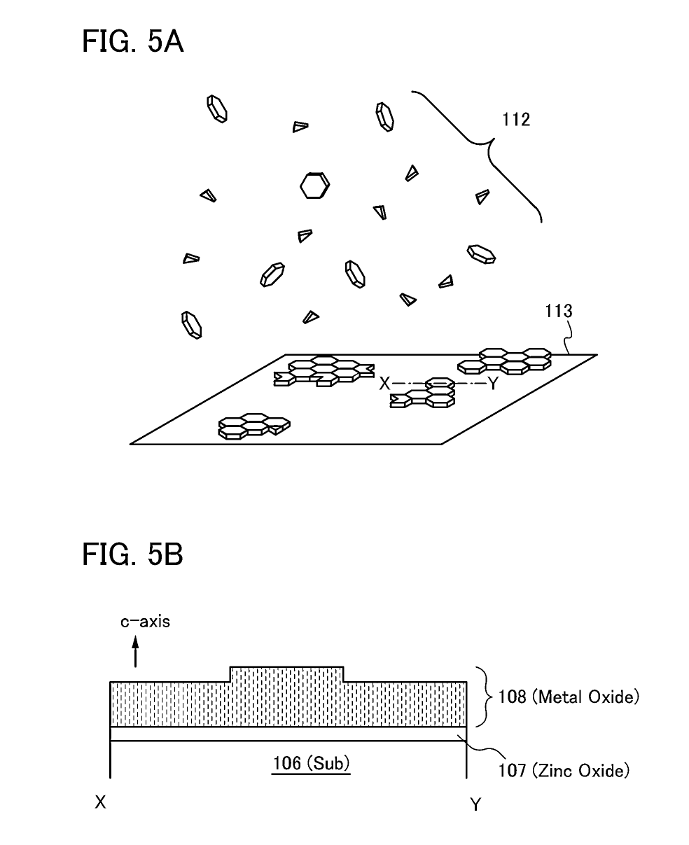

A state in which sputtered particles are deposited on a deposition surface is described below with reference to FIGS. 5A and 5B.

In FIG. 5A, a deposition surface 113 has a surface on which the sputtered particles 112 are deposited. As shown in FIG. 5A, the sputtered particle 112 is positively or negatively charged, and accordingly the sputtered particle 112 is deposited on a region where other sputtered particles 112 have not been deposited yet. This is because the sputtered particles 112 which are charged repel with each other. At this time, by being affected by the sputtered particles 112 which have been already deposited, the sputtered particle 112 is deposited so that its a-axis, b-axis, and c-axis are oriented along the a-axes, the b-axes, and the c-axes of the sputtered particles 112.

A metal oxide film which is obtained by deposition has a uniform thickness. The sputtered particles are not deposited randomly. The sputtered particles are charged interact with each other and are deposited orderly in a direction perpendicular to the deposition surface so as to be aligned in not only c-axes but also a-axes and b-axes.

In particular, in the target 100 including a c-axis-aligned polycrystalline metal oxide, decreasing the crystallinity of the surface of the target 100 can be suppressed. When the crystallinity of the surface of the target 100 is not decreased, the crystallinity of the sputtered particle 112 is kept and thus, the metal oxide film 108 having favorable crystallinity can be obtained. This is because the sputtered particle 112 having favorable crystallinity is deposited according to the crystallinity of the deposition surface 113.

In contrast, when the crystallinity of the surface of the target 100 is decreased, the sputtered particles 112 and the deposition surface 113 on which the sputtered particles 112 are deposited have low crystallinity, and thus are easily disordered.

FIG. 5B is a cross-sectional view taken along dashed-dotted line X-Y in FIG. 5A. The deposited sputtered particles 112 form the metal oxide film 108 in which c-axes of crystals are aligned in a direction perpendicular to the deposition surface 113 (CAAC metal oxide film). Further, since the metal oxide film 108 is deposited according to the crystallinity of the zinc oxide film 107 formed under the metal oxide film 108, the metal oxide film 108 becomes a single crystal with a certain size.

In other words, a single-crystal metal oxide thin film having an area of 5 μm² or more, preferably 1000 μm² or more. Further, the single-crystal thin film is positioned over the zinc oxide film. Note that the metal oxide film 108 does not necessarily include a single-crystal region.

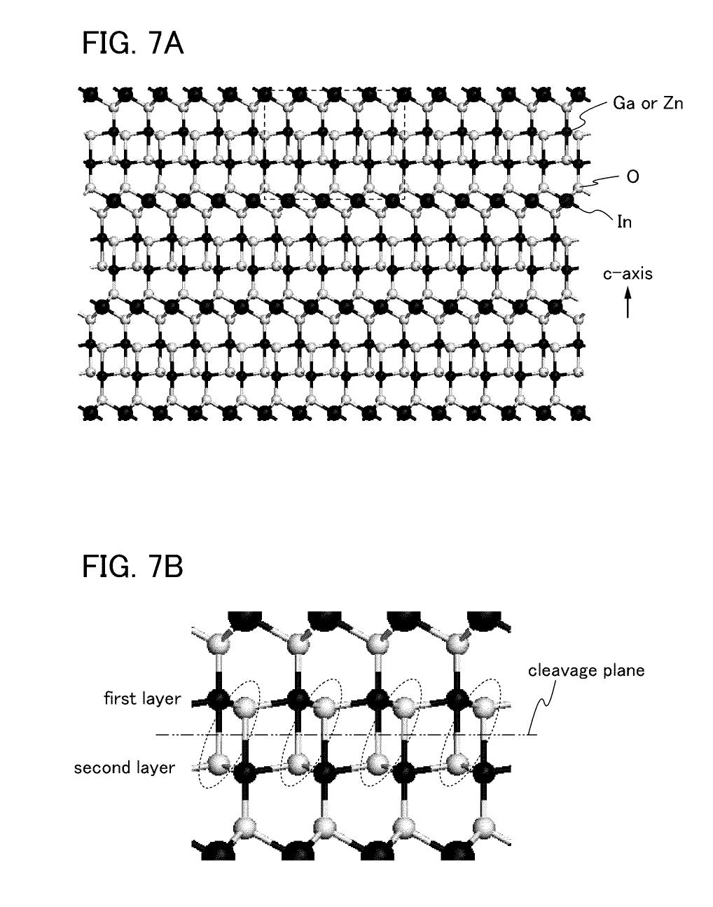

FIG. 7A illustrates an example of the crystal structure of an In—Ga—Zn oxide viewed from a direction parallel to an a-b plane. Further, FIG. 7B illustrates an enlarged portion surrounded by a dashed line in FIG. 7A.

For example, in a crystal grain of an In—Ga—Zn oxide, a cleavage plane is a plane between a first layer and a second layer as illustrated in FIG. 7B. The first layer includes a gallium atom and/or zinc atom and an oxygen atom, and the second layer includes a gallium atom and/or zinc atom and an oxygen atom. This is because oxygen atoms having negative charge in the first layer and oxygen atoms having negative charge in the second layer are close to each other (see a portion surrounded by a dotted line in FIG. 7B). Since the cleavage plane is a flat plane parallel to an a-b plane, the sputtered particle including an In—Ga—Zn oxide has a flat-plate-like shape having a flat plane parallel to an a-b plane.

In the In—Ga—Zn oxide, a bond between an indium atom and an oxygen atom is weak and cut most easily, and oxygen vacancies are likely to be generated. As described above, the crystal of the In—Ga—Zn oxide has a plurality of planes which are perpendicular to an a-b plane and generated when the bonds between indium atoms and oxygen atoms are cut.

The crystal of the In—Ga—Zn oxide is a hexagonal crystal; thus, the flat-plate-like sputtered particle is likely to have a hexagonal prism shape with a regular hexagonal plane whose internal angle is 120°. Note that the flat-plate-like sputtered particle is not limited to a hexagonal prism shape, and in some cases, it has a triangular prism shape with a regular triangular plane whose internal angle is 60° or a polygonal prism shape different from the above shapes.

The above oxygen vacancies are filled by being bonded to oxygen ions in the sputtering gas in some cases. Note that heat treatment is preferably performed on the deposited crystalline metal oxide film in an oxidation atmosphere in order to reduce oxygen vacancies.

By depositing sputtered particles as described in this embodiment, at least a crystalline metal oxide can be formed. Further, the crystalline metal oxide formed in such a manner can be a single crystal or a film equivalent to a single crystal in some cases.

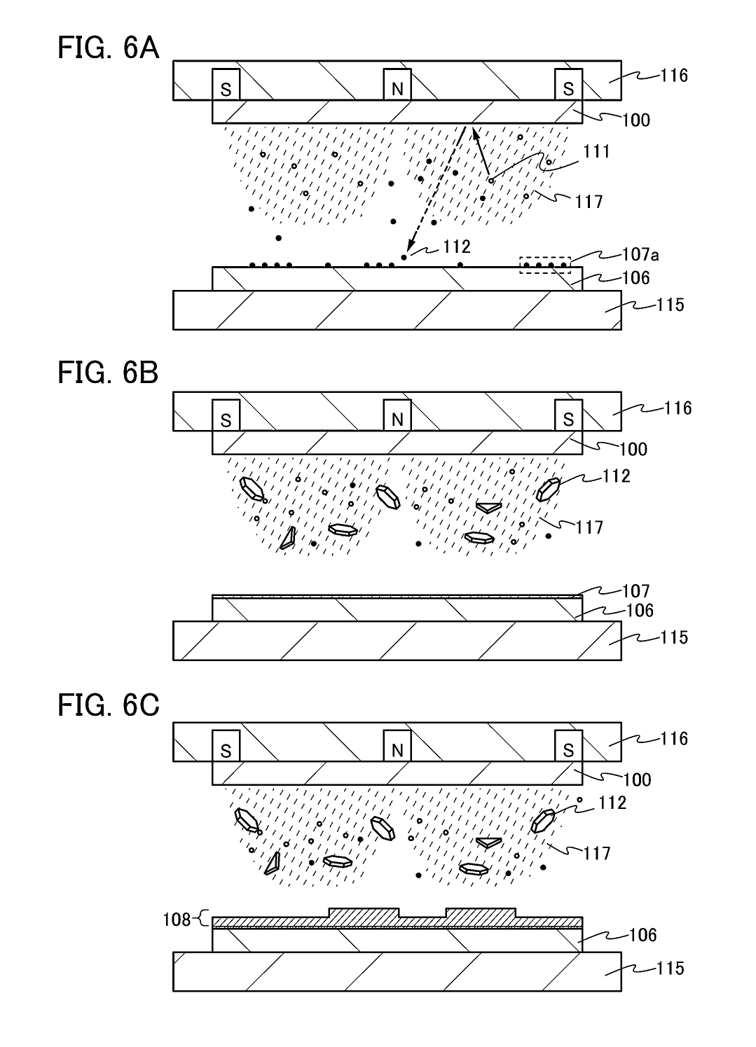

Although the above is an example where the metal oxide film 108 is deposited after the zinc oxide film 107 is deposited, the metal oxide film 108 including a single-crystal region can be obtained by similar mechanism without depositing the zinc oxide film 107. The example is illustrated in FIGS. 6A to 6C.

As illustrated in FIG. 6A, the substrate 106 fixed to a substrate holder 115 faces the target 100 fixed to a target holder 116 and manufactured in Embodiment 1. A sputtering gas such as oxygen or an inert gas such as argon is introduced, and a voltage is applied to the target 100 to generate plasma 117. The sputtering gas is ionized in the plasma 117, and ions 111 are generated. When the ions 111 collide with the target 100, interatomic bonds in the target 100 are cut and the sputtered particles 112 are separated from the target 100. Therefore, the ions 111, the sputtered particles 112, electrons, and/or the like exist in the plasma 117.

In the case of an In—Ga—Zn oxide target, examples of the sputtered particles 112 in FIG. 6A include zinc particles, oxygen particles, zinc oxide particles, In—Ga—Zn oxide particles, and the like. In the case of the target 100 containing more Zn than Ga, zinc particles, oxygen particles, and zinc oxide particles are preferentially separated from the target 100.

First, zinc particles and oxygen particles are separated as the sputtered particles 112 from the target 100. Next, the zinc particles and the oxygen particles move to the substrate, whereby zinc oxide particles 107a are formed over the substrate as illustrated in FIG. 6A.

The crystal of zinc oxide grows rapidly in a direction parallel to an a-b plane. Therefore, the crystal of the zinc oxide particles 107a grows in a direction parallel to a surface of the substrate 106, that is, in a lateral direction, at a substrate temperature higher than or equal to 200° C. and lower than 500° C. As a result, the zinc oxide film 107 is formed as illustrated in FIG. 6B. Note that the zinc oxide film 107 may include a non-single-crystal region.

At this time, it is important that the zinc oxide film 107 is sufficiently thin. This is because when the zinc oxide film 107 is sufficiently thin, the zinc oxide film 107 is likely to be affected by adjacent crystals and thus, arrangement of crystals is easily changed depending on the adjacent crystals. As a result, a single-crystal region is expanded in the zinc oxide film 107. In the zinc oxide film with a certain thickness, such a change is difficult and a state where crystal orientations are different between adjacent crystals, that is, a grain boundary, occurs.

After that, the sputtered particles 112 other than oxygen and zinc, for example, In—Ga—Zn oxide particles, are separated and deposited over the zinc oxide film 107, so that the metal oxide film 108 including an In—Ga—Zn oxide is formed as illustrated in FIG. 6C. Note that zinc particles, oxygen particles, and zinc oxide particles are also deposited as sputtered particles in this step. The In—Ga—Zn oxide particles are deposited according to the crystallinity of the single-crystal zinc oxide film 107; thus, a single-crystal thin film having a corresponding area is formed in some cases.

Note that it is difficult to obtain a crystalline thin film of an In—Ga—Zn oxide containing much Ga at a substrate temperature lower than or equal to 500° C.; however, the crystalline thin film can be easily obtained in the case where the film is formed over the zinc oxide film 107.

By utilizing its property, single-crystal thin films of metal oxide films having different properties and compositions can be formed. For example, as illustrated in FIG. 3E, when a second metal oxide film 108b is deposited over a first metal oxide film 108a, each of the first metal oxide film 108a and the second metal oxide film 108b becomes single crystals in a corresponding region in some cases.

For example, in the case where the target used for the first metal oxide film 108a has a composition of indium:gallium:zinc=1:3:4, when the film is directly deposited on an amorphous surface, a crystal structure other than a desired one is obtained, or sufficiently high crystallinity cannot be obtained in some cases; however, when the film is formed over the c-axis-aligned zinc oxide film 107, desired crystallinity can be obtained.

The bandgap of the first metal oxide film 108a obtained in the case where the composition of the target is indium:gallium:zinc=1:3:4 is slightly wider than that of the second metal oxide film 108b obtained in the case where the composition of the target is indium:gallium:zinc=1:1:1; thus, the main path of current in the stack is the second metal oxide film 108b, and the first metal oxide film 108a serves as a buffer layer.

Similarly, a third metal oxide film 108c may be further deposited. In that case, for example, when the target having a composition of indium:gallium:zinc=1:3:4 is used for the third metal oxide film 108c, the second metal oxide film 108b is sandwiched between the first metal oxide film 108a and the third metal oxide film 108c each of which has a bandgap wider than that of the second metal oxide film 108b; thus, a buried channel can be obtained.

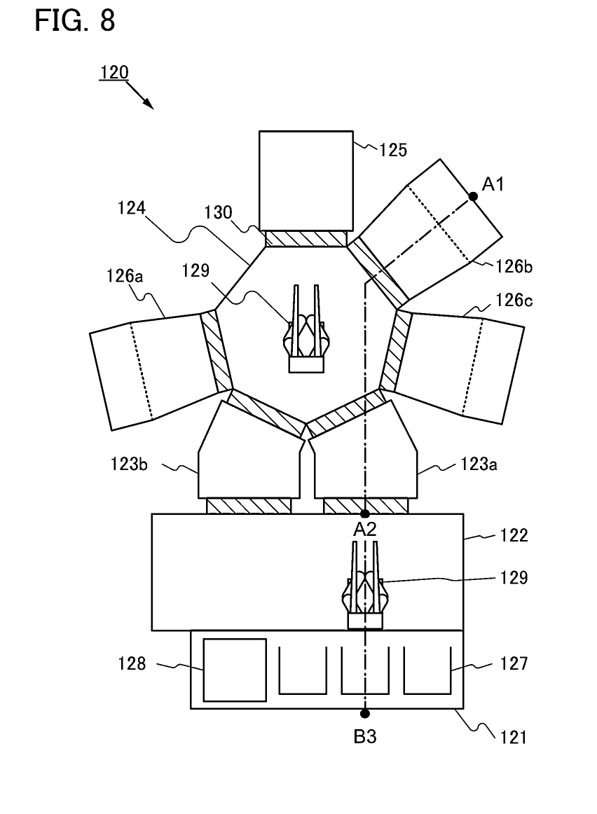

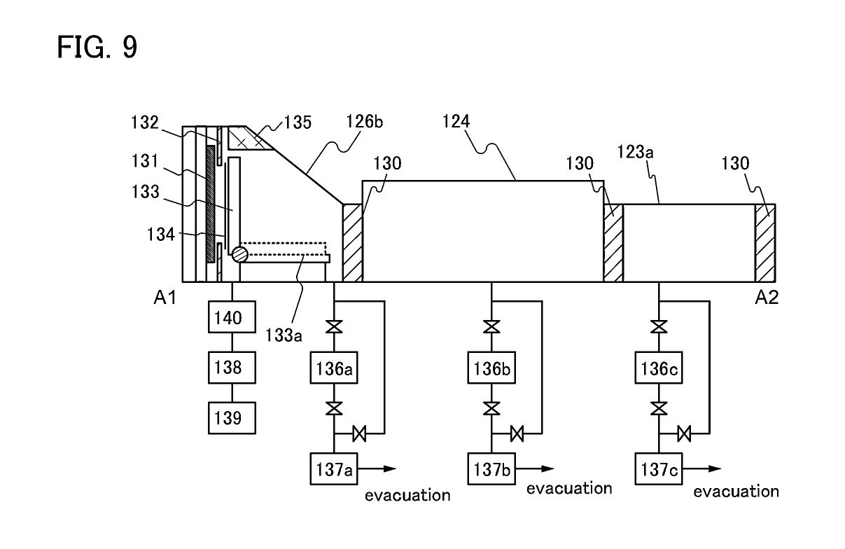

Next, a structure of a deposition apparatus that hardly allows the entry of impurities into a film during deposition will be described with reference to FIG. 8 and FIG. 9.

FIG. 8 is a schematic top view of a single wafer multi-chamber deposition apparatus 120. The deposition apparatus 120 includes an atmosphere-side substrate supply chamber 121 including a cassette port 127 for storing substrates and an alignment port 128 for performing alignment of substrates, an atmosphere-side substrate transfer chamber 122 through which a substrate is transferred from the atmosphere-side substrate supply chamber 121, a load lock chamber 123a where a substrate is carried in and the pressure is switched from atmospheric pressure to reduced pressure or from reduced pressure to atmospheric pressure, an unload lock chamber 123b where a substrate is carried out and the pressure is switched from reduced pressure to atmospheric pressure or from atmospheric pressure to reduced pressure, a transfer chamber 124 where a substrate is transferred in a vacuum, a substrate heating chamber 125 where a substrate is heated, and deposition chambers 126a, 126b, and 126c in each of which a target is placed for deposition.

Note that a plurality of cassette ports 127 may be provided as illustrated in FIG. 8 (in FIG. 8, three cassette ports 127 are provided).

The atmosphere-side substrate transfer chamber 122 is connected to the load lock chamber 123a and the unload lock chamber 123b, the load lock chamber 123a and the unload lock chamber 123b are connected to the transfer chamber 124, and the transfer chamber 124 is connected to the substrate heating chamber 125 and the deposition chambers 126a, 126b, and 126c.

Note that gate valves 130 are provided in connecting portions between the chambers so that each chamber excluding the atmosphere-side substrate supply chamber 121 and the atmosphere-side substrate transfer chamber 122 can be independently kept in a vacuum state. In each of the atmosphere-side substrate supply chamber 122 and the transfer chamber 124, a substrate transfer robot 129 is provided, which is capable of transferring substrates.

In the deposition apparatus 120, substrates can be transferred without being exposed to the air between treatments, and adsorption of impurities to substrates can be suppressed. Note that the number of transfer chambers, the number of deposition chambers, the number of load lock chambers, the number of unload lock chambers, and the number of substrate heating chambers are not limited to the above, and the numbers thereof can be set as appropriate depending on the space for installation or the process conditions.

A heating mechanism which can be used in the substrate heating chamber 125 may be a heating mechanism which uses a resistance heater, a lamp, or the like for heating. Alternatively, heat conduction or heat radiation from a medium such as a heated gas may be used as the heating mechanism. For example, rapid thermal annealing (RTA), such as gas rapid thermal annealing (GRTA) or lamp rapid thermal annealing (LRTA), can be used. In LRTA, an object is heated by radiation of light (an electromagnetic wave) emitted from a lamp, such as a halogen lamp, a metal halide lamp, a xenon arc lamp, a carbon arc lamp, a high-pressure sodium lamp, or a high-pressure mercury lamp. In GRTA, heat treatment is performed using a high-temperature gas. As the gas, an inert gas is used.

The transfer chamber 124 includes the substrate transfer robot 129. The substrate transfer robot 129 includes a plurality of movable portions and an arm for holding a substrate and can transfer a substrate to each chamber.

Next, FIG. 9 is a cross-sectional view taken along dashed-dotted line A1-A2 in the deposition apparatus 120 illustrated in FIG. 8. FIG. 9 shows a cross section of the deposition chamber 126b, the transfer chamber 124, and the load lock chamber 123a.

The transfer chamber 124 is connected to a vacuum pump 137b and a turbo molecular pump 136b through valves. With such a structure, the transfer chamber 124 is evacuated from the atmospheric pressure to a low or medium vacuum (about 0.1 Pa to several hundred pascals) by using the vacuum pump 137b and then evacuated from the medium vacuum to a high or ultrahigh vacuum (0.1 Pa to 1×10⁻⁷ Pa) by switching between the valves and using the turbo molecular pump 136b.

Note that a cryopump may be used instead of the turbo molecular pump 136b. Alternatively, two or more cryopumps may be connected in parallel to the transfer chamber 124. With such a structure, even when one of the cryopumps is in regeneration (treatment for discharging molecules (or atoms) trapped in the cryopump), evacuation can be performed using any of the other cryopumps. When molecules (or atoms) are trapped too much in a cryopump, the evacuation capability of the cryopump is lowered; therefore, regeneration is performed regularly.

The load lock chamber 123a is connected to a vacuum pump 137c and a turbo molecular pump 136c through valves. With such a structure, the load lock chamber 123a is evacuated from the atmospheric pressure to a low or medium vacuum (about 0.1 Pa to several hundred pascals) by using the vacuum pump 137c and then evacuated from the medium vacuum to a high or ultrahigh vacuum (0.1 Pa to 1×10⁻⁷ Pa) by switching between the valves and using the turbo molecular pump 136c.

Here, the details of the deposition chamber 126b will be described. Here, deposition using a sputtering method is performed in the deposition chamber 126b. Note that in the deposition chamber 126b in this embodiment, a sputtering target and a substrate are illustrated as being placed vertically.

The deposition chamber 126b illustrated in FIG. 9 includes a target 131, a deposition shield 132, and a substrate stage 133. Note that the substrate stage 133 here is provided with a substrate 134. Although not illustrated, the substrate stage 133 may be provided with a substrate holding mechanism for holding the substrate 134, a back side heater for heating the substrate 134 from the back side, or the like.

A direct-current (DC) power source is preferably used as a power source for applying a voltage to a sputtering target. Alternatively, a radio frequency (RF) power source or an alternating-current (AC) power source can be used. However, in the case of using a sputtering method with an RF power source, uniform plasma discharge to a large area is difficult. In addition, a DC power source is preferred to an AC power source from the following viewpoint.

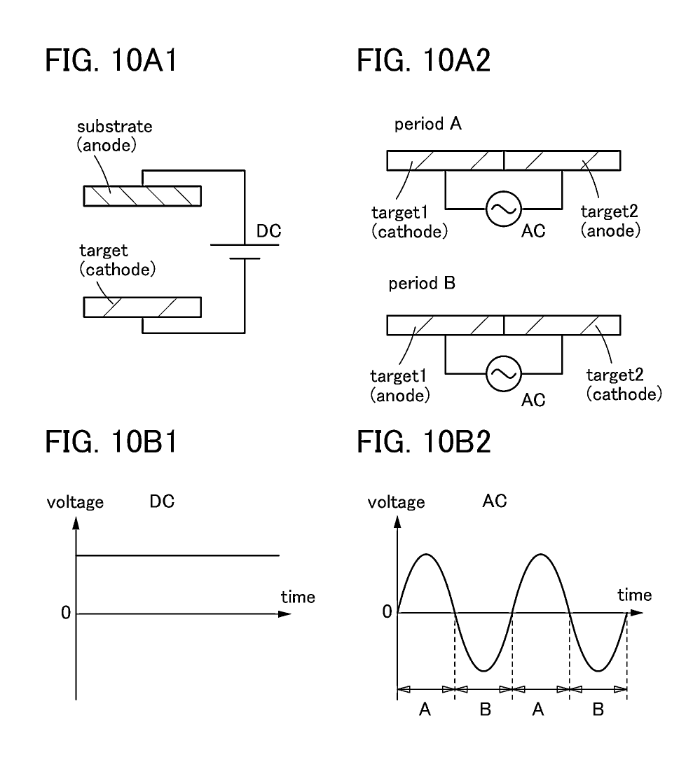

In a sputtering method using a DC power source, a DC voltage is applied between a sputtering target and a substrate as illustrated in FIG. 10A1, for example. Accordingly, the voltage between the sputtering target and the substrate is constant regardless of time as shown in FIG. 10B1. Thus, the sputtering method using a DC power source can maintain constant plasma discharge.

In contrast, in a sputtering method using an AC power source, a cathode and an anode switch between adjacent sputtering targets on the period basis (period A and period B) as illustrated in FIG. 10A2, for example. In period A in FIG. 10B2, for example, a sputtering target 1 functions as a cathode and a sputtering target 2 functions as an anode. Further, in period B in FIG. 10B2, for example, the sputtering target 1 functions as an anode and the sputtering target 2 functions as a cathode. The sum of period A and period B is approximately 20 microseconds to 50 microseconds, for example. Thus, in the sputtering method using an AC power source, plasma is discharged during alternating periods A and B.

Note that the substrate stage 133 is held substantially vertically to a floor during deposition and is held substantially parallel to the floor when the substrate is delivered. In FIG. 9, a reference numeral 133a denoted by a dashed line indicates the position where the substrate stage 133 is held when the substrate is delivered. With such a structure, the probability that dust or a particle which might be mixed into a film during deposition is attached to the substrate 134 can be lowered as compared to the case where the substrate stage 133 is held parallel to the floor. However, there is a possibility that the substrate 134 falls when the substrate stage 133 is held vertically) (90° to the floor; therefore, the angle of the substrate stage 133 to the floor is preferred to be greater than or equal to 80° and lower than 90°.

The deposition shield 132 can prevent sputtered particles separated from the target 131 from being deposited on a region where deposition is not necessary. Moreover, the deposition shield 132 is preferably processed to prevent accumulated sputtered particles from being separated. For example, blasting treatment which increases surface roughness may be performed on the deposition shield 132, or a roughness may be formed on the surface of the deposition shield 132.

The deposition chamber 126b is connected to a mass flow controller 138 via a gas heating mechanism 140, and the gas heating mechanism 140 is connected to a refiner 139 via the mass flow controller 138. With the gas heating mechanism 140, gases to be introduced into the deposition chamber 126b can be heated to a temperature higher than or equal to 40° C. and lower than or equal to 400° C., preferably higher than or equal to 50° C. and lower than or equal to 200° C. Note that although the gas heating mechanism 140, the mass flow controller 138, and the refiner 139 can be provided for each of a plurality of kinds of gases, only one gas heating mechanism 140, one mass flow controller 138, and one refiner 139 are provided for simplicity. As the gas introduced into the deposition chamber 126b, a gas whose dew point is −60° C. or lower, −100° C. or lower, or −120° C. or lower can be used; for example, an oxygen gas, a nitrogen gas, and a rare gas (e.g., an argon gas) are used.

The deposition chamber 126b is connected to a turbo molecular pump 136a and a vacuum pump 137a via valves.

In addition, the deposition chamber 126b is provided with a cryotrap 135.

The cryotrap 135 is a mechanism which can adsorb a molecule (or an atom) having a relatively high melting point, such as water. The turbo molecular pump 136a is capable of stably evacuating a large-sized molecule (or atom), needs low frequency of maintenance, and thus enables high productivity, whereas it has a low capability in evacuating hydrogen and water. Hence, the cryotrap 135 is connected to the deposition chamber 126b so as to have a high capability in evacuating water or the like. The temperature of a refrigerator of the cryotrap 135 is 100 K or lower, preferably 80 K or lower. In the case where the cryotrap 135 includes a plurality of refrigerators, it is preferable to set the temperatures of the refrigerators at different temperatures because efficient evacuation is possible. For example, the temperatures of a first-stage refrigerator and a second-stage refrigerator may be set to 100 K or lower and 20 K or lower, respectively.

Note that the evacuation method of the deposition chamber 126b is not limited to the above, and the evacuation method using the cryopump and the vacuum pump may be employed.

Note that in each of the above transfer chamber 124, the substrate heating chamber 125, and the deposition chamber 126b, the back pressure (total pressure) and the partial pressure of each gas molecule (atom) are preferably set as follows. In particular, the back pressure and the partial pressure of each gas molecule (atom) in the deposition chamber 126b need to be noted because impurities might enter a film to be formed.

In each of the above chambers, the back pressure (total pressure) is less than or equal to 1×10⁻⁴ Pa, preferably less than or equal to 3×10⁻⁵ Pa, more preferably less than or equal to 1×10⁻⁵ Pa. In each of the above chambers, the partial pressure of a gas molecule (atom) having a mass-to-charge ratio (m/z) of 18 is less than or equal to 3×10⁻⁵ Pa, preferably less than or equal to 1×10⁻⁵ Pa, more preferably less than or equal to 3×10⁻⁶ Pa. Moreover, in each of the above chambers, the partial pressure of a gas molecule (atom) having a mass-to-charge ratio (m/z) of 28 is less than or equal to 3×10⁻⁵ Pa, preferably less than or equal to 1×10⁻⁵ Pa, more preferably less than or equal to 3×10⁻⁶ Pa. Moreover, in each of the above chambers, the partial pressure of a gas molecule (atom) having a mass-to-charge ratio (m/z) of 44 is less than or equal to 3×10⁻⁵ Pa, preferably less than or equal to 1×10⁻⁵ Pa, more preferably less than or equal to 3×10⁻⁶ Pa.

Note that a total pressure and a partial pressure in a vacuum chamber can be measured using a mass analyzer. For example, Qulee CGM-051, a quadrupole mass analyzer (also referred to as Q-mass) manufactured by ULVAC, Inc. can be used.

Moreover, the above transfer chamber 124, the substrate heating chamber 125, and the deposition chamber 126b preferably have a small amount of external leakage or internal leakage.

For example, in each of the above transfer chamber 124, the substrate heating chamber 125, and the deposition chamber 126b, the leakage rate is less than or equal to 3×10⁻⁶ Pa·m³/s, preferably less than or equal to 1×10⁻⁶ Pa·m³/s. The leakage rate of a gas molecule (atom) having a mass-to-charge ratio (m/z) of 18 is less than or equal to 1×10⁻⁷ Pa·m³/s, preferably less than or equal to 3×10⁻⁸ Pa·m³/s. The leakage rate of a gas molecule (atom) having a mass-to-charge ratio (m/z) of 28 is less than or equal to 1×10⁻⁵ Pa·m³/s, preferably less than or equal to 1×10⁻⁶ Pa·m³/s. The leakage rate of a gas molecule (atom) having a mass-to-charge ratio (m/z) of 44 is less than or equal to 3×10⁻⁶ Pa·m³/s, preferably less than or equal to 1×10⁻⁶ Pa·m³/s.

Note that a leakage rate can be derived from the total pressure and partial pressure measured using the mass analyzer.

When an oxide film is formed with the use of the above deposition apparatus, the entry of impurities to the oxide film can be suppressed.

Note that although an oxide semiconductor film including a single-crystal region is formed using a c-axis-aligned target in this embodiment, an amorphous oxide semiconductor film can be formed over a c-axis-aligned zinc oxide film by using the c-axis-aligned target described in this embodiment.

### Embodiment 2

In this embodiment, a semiconductor device which is one embodiment of the present invention and a manufacturing method thereof are described with reference to drawings.

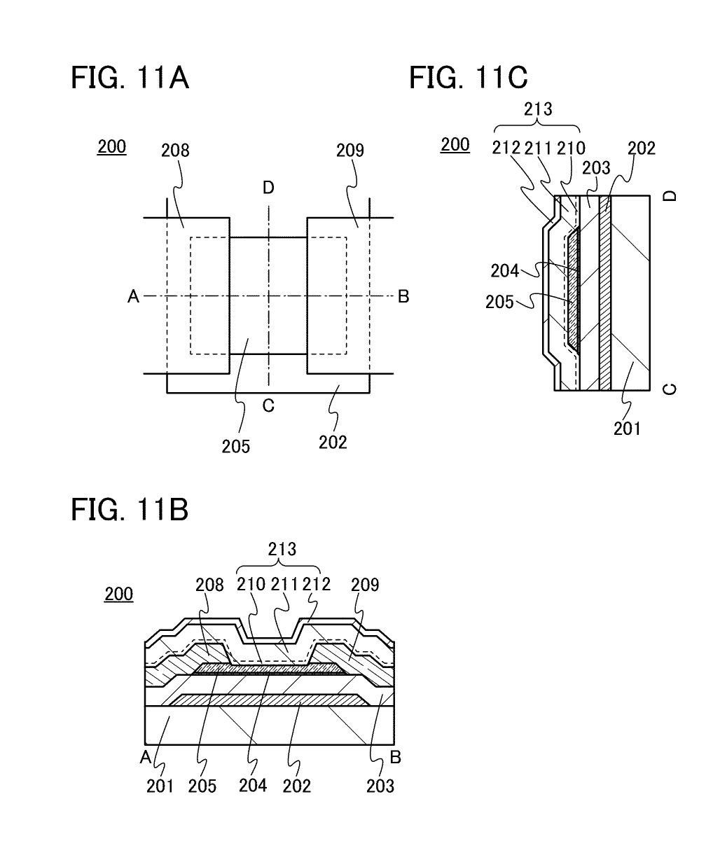

FIGS. 11A to 11C are a top view and cross-sectional views of a transistor 200 of a semiconductor device. The transistor 200 shown in FIGS. 11A to 11C is a channel-etched transistor. FIG. 11A is a top view of the transistor 200, FIG. 11B is a cross-sectional view taken along dashed-dotted line A-B in FIG. 11A, and FIG. 11C is a cross-sectional view taken along dashed-dotted line C-D in FIG. 11A. Note that in FIG. 11A, some components of the transistor 200 (e.g., a substrate 201, a gate insulating film 203, an oxide insulating film 210, an oxide insulating film 211, a nitride insulating film 212, and the like) are not illustrated for clarity.

The transistor 200 shown in FIGS. 11B and 11C includes a gate electrode 202 provided over the substrate 201. Moreover, the gate insulating film 203 over the substrate 201 and the gate electrode 202, an oxide semiconductor layer 205 which is over the gate insulating film 203 and overlaps with the gate electrode 202, a zinc oxide layer 204 in close contact with a bottom surface of the oxide semiconductor layer 205, and a pair of electrodes 208 and 209 being in contact with the oxide semiconductor layer 205 are included. Furthermore, a protective film 213 including the oxide insulating film 210, the oxide insulating film 211, and the nitride insulating film 212 is formed over the gate insulating film 203, the oxide semiconductor layer 205, and the pair of electrodes 208 and 209.

In the transistor 200 described in this embodiment, part of the oxide semiconductor layer 205 serves as a channel region. Further, the oxide insulating film 210 is formed in contact with the oxide semiconductor layer 205, and the oxide insulating film 211 is formed in contact with the oxide insulating film 210.

The oxide semiconductor layer 205 is typically an In-M-Zn oxide (M is aluminum, tin, gallium, yttrium, zirconium, lanthanum, cerium, or neodymium).

The energy gap of the oxide semiconductor layer 205 is 2 eV or more, preferably 2.5 eV or more, more preferably 3 eV or more. With the use of an oxide semiconductor having such a wide energy gap, the off-state current of the transistor 200 can be reduced.

The average thickness of the oxide semiconductor layer 205 is less than or equal to 500 nm, preferably greater than or equal to 5 nm and less than or equal to 100 nm.

The oxide semiconductor layer 205 is preferably formed using the sputtering target described in Embodiment 1, and typically, a sputtering target of a c-axis-aligned polycrystalline oxide with an atomic ratio of indium:galium:zinc=1:1:1.05 to 1:1:1.5 can be used. Note that the atomic ratio of M to In and the atomic ratio of Zn to In in the oxide semiconductor layer 205 formed using such a sputtering target are lower than those in the sputtering target.

An oxide semiconductor film with low carrier density is used as the oxide semiconductor layer 205. For example, an oxide semiconductor film whose carrier density is 1×10¹⁷/cm³ or lower, preferably 1×10¹⁵/cm³ or lower, more preferably 1×10¹³/cm³ or lower, much more preferably 1×10¹¹/cm³ or lower is used as the oxide semiconductor layer 205.

Note that, without limitation to that described above, a material with an appropriate composition may be used depending on required semiconductor characteristics and electrical characteristics (e.g., field-effect mobility and threshold voltage) of a transistor. Further, in order to obtain required semiconductor characteristics and electrical characteristics of a transistor, it is preferable that the carrier density, the impurity concentration, the defect density, the atomic ratio of a metal element to oxygen, the interatomic distance, the density, and the like of the oxide semiconductor layer 205 be set to be appropriate.

Hydrogen contained in the oxide semiconductor film reacts with oxygen bonded to a metal atom to form water, and in addition, an oxygen vacancy is formed in a lattice from which oxygen is released (or a portion from which oxygen is released). Due to entry of hydrogen into the oxygen vacancy, an electron serving as a carrier is generated in some cases. Further, in some cases, bonding of part of hydrogen to oxygen bonded to a metal element causes generation of an electron serving as a carrier. Thus, a transistor including an oxide semiconductor which contains hydrogen is likely to be normally on.

Accordingly, it is preferable that hydrogen be reduced as much as possible in the oxide semiconductor layer 205. Specifically, the hydrogen concentration of the oxide semiconductor layer 205, which is measured by secondary ion mass spectrometry (SIMS), is lower than or equal to 2×10²⁰ atoms/cm³, lower than or equal to 5×10¹⁹ atoms/cm³, lower than or equal to 1×10¹⁹ atoms/cm³, lower than 5×10¹⁸ atoms/cm³, lower than or equal to 1×10¹⁸ atoms/cm³, lower than or equal to 5×10¹⁷ atoms/cm³, or lower than or equal to 1×10¹⁶ atoms/cm³.

When silicon or carbon which is one of elements belonging to Group 14 is contained in the oxide semiconductor layer 205, oxygen vacancies are increased, and the oxide semiconductor layer 205 becomes an n-type film. Thus, the concentration of silicon or carbon (the concentration is measured by SIMS) of the oxide semiconductor layer 205 is lower than or equal to 2×10¹⁸ atoms/cm³, preferably lower than or equal to 2×10¹⁷ atoms/cm³.

Further, the concentration of alkali metal or alkaline earth metal of the oxide semiconductor layer 205, which is measured by SIMS, is lower than or equal to 1×10¹⁸ atoms/cm³, preferably lower than or equal to 2×10¹⁶ atoms/cm³. Alkali metal and alkaline earth metal might generate carriers when bonded to an oxide semiconductor, in which case the off-state current of the transistor might be increased. Therefore, it is preferable to reduce the concentration of alkali metal or alkaline earth metal of the oxide semiconductor layer 205.

Further, when containing nitrogen, the oxide semiconductor layer 205 easily has n-type conductivity by generation of electrons serving as carriers and an increase of carrier density. Thus, a transistor including an oxide semiconductor which contains nitrogen is likely to be normally on. For this reason, nitrogen in the oxide semiconductor film is preferably reduced as much as possible; the concentration of nitrogen which is measured by SIMS is preferably set to, for example, lower than or equal to 5×10¹⁸ atoms/cm³.

Further, the oxide semiconductor layer 205 is formed over the single-crystal zinc oxide layer 204 according to the deposition model described in Embodiment 1. Thus, the oxide semiconductor layer 205 includes a single-crystal region with an area of 5 μm² or more, preferably 1000 μm² or more.

The oxide insulating film 210 is an oxide insulating film which is permeable to oxygen. Note that the oxide insulating film 210 also serves as a film which relieves damage to the oxide semiconductor layer 205 at the time of forming the oxide insulating film 211 later.

A silicon oxide film, a silicon oxynitride film, or the like with a thickness greater than or equal to 5 nm and less than or equal to 150 nm, preferably greater than or equal to 5 nm and less than or equal to 50 nm can be used as the oxide insulating film 210. Note that in this specification, a “silicon oxynitride film” refers to a film that contains oxygen at a higher proportion than nitrogen, and a “silicon nitride oxide film” refers to a film that contains nitrogen at a higher proportion than oxygen.

Further, it is preferable that the amount of defects in the oxide insulating film 210 be small, and typically the spin density corresponding to a signal which appears at g=2.001 due to a dangling bond of silicon, be lower than or equal to 3×10¹⁷ spins/cm³ by ESR measurement. This is because if the density of defects in the oxide insulating film 210 is high, oxygen is bonded to the defects and the amount of oxygen that permeates the oxide insulating film 210 is decreased.

Further, it is preferable that the amount of defects at the interface between the oxide insulating film 210 and the oxide semiconductor layer 205 be small, and typically the spin density corresponding to a signal which appears at g=1.93 due to an defect in the oxide semiconductor layer 205 be lower than or equal to 1×10¹⁷ spins/cm³, more preferably lower than or equal to the lower limit of detection by ESR measurement.

The oxide insulating film 211 is formed in contact with the oxide insulating film 210. The oxide insulating film 211 is formed using an oxide insulating film which contains oxygen at a higher proportion than the stoichiometric composition. Part of oxygen is released by heating from the oxide insulating film which contains oxygen at a higher proportion than the stoichiometric composition. The oxide insulating film containing oxygen at a higher proportion than the stoichiometric composition is an oxide insulating film of which the amount of released oxygen converted into oxygen atoms is greater than or equal to 1.0×10¹⁸ atoms/cm³, preferably greater than or equal to 3.0×10²⁰ atoms/cm³ in TDS analysis.

A silicon oxide film, a silicon oxynitride film, or the like with a thickness greater than or equal to 50 nm and less than or equal to 400 nm can be used as the oxide insulating film 211.

Further, it is preferable that the amount of defects in the oxide insulating film 211 be small, typically the spin density corresponding to a signal which appears at g=2.001 due to a dangling bond of silicon, be lower than 1.5×10¹⁸ spins/cm³, more preferably lower than or equal to 1×10¹⁸ spins/cm³ by ESR measurement. Note that the oxide insulating film 211 is provided more apart from the oxide semiconductor layer 205 than the oxide insulating film 210 is; thus, the oxide insulating film 211 may have higher defect density than the oxide insulating film 210.

Further, it is possible to prevent outward diffusion of oxygen from the oxide semiconductor layer 205 and entry of hydrogen, water, or the like into the oxide semiconductor layer 205 from the outside by providing the nitride insulating film 212 having a blocking effect against oxygen, hydrogen, water, alkali metal, alkaline earth metal, and the like over the oxide insulating film 211. The nitride insulating film is silicon nitride, silicon nitride oxide, aluminum nitride, aluminum nitride oxide, or the like. Note that instead of the nitride insulating film having a blocking effect against oxygen, hydrogen, water, alkali metal, alkaline earth metal, and the like, an oxide insulating film having a blocking effect against oxygen, hydrogen, water, and the like, may be provided. As the oxide insulating film having a blocking effect against oxygen, hydrogen, water, and the like, aluminum oxide, aluminum oxynitride, gallium oxide, gallium oxynitride, yttrium oxide, yttrium oxynitride, hafnium oxide, and hafnium oxynitride can be given.

The gate electrode 202 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal element.

The gate insulating film 203 can be formed to have a single-layer structure or a stacked-layer structure using, for example, any of silicon oxide, silicon oxynitride, silicon nitride oxide, silicon nitride, aluminum oxide, hafnium oxide, gallium oxide, Ga—Zn-based metal oxide, and the like.

The gate insulating film 203 may be formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), hafnium oxide, or yttrium oxide.

The thickness of the gate insulating film 203 is preferably greater than or equal to 5 nm and less than or equal to 400 nm, more preferably greater than or equal to 10 nm and less than or equal to 300 nm, still more preferably greater than or equal to 50 nm and less than or equal to 250 nm.

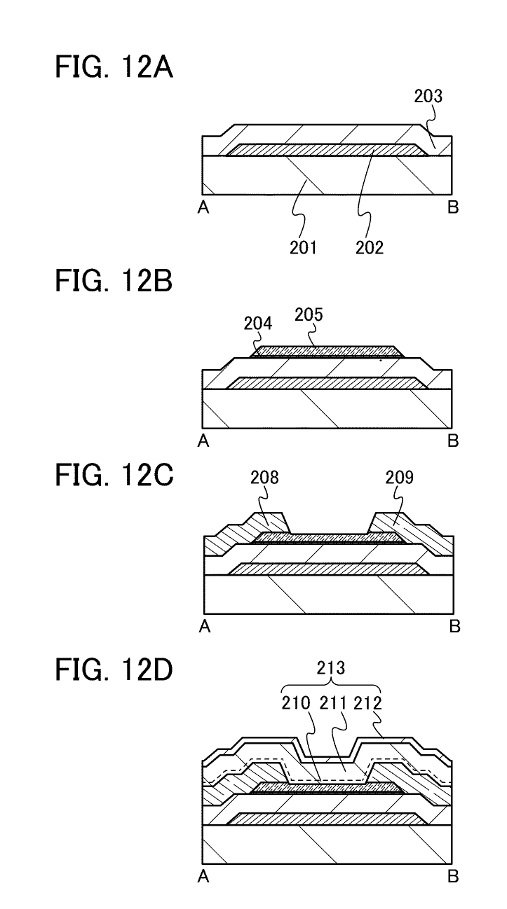

Next, a method for manufacturing the transistor 200 illustrated in FIGS. 11A to 11C is described with reference to FIGS. 12A to 12D.

As illustrated in FIG. 12A, the gate electrode 202 is formed over the substrate 201, and the gate insulating film 203 is formed over the gate electrode 202. For example, a glass substrate is used as the substrate 201.

A method for forming the gate electrode 202 is described below. First, a conductive film is formed by a sputtering method, a CVD method, an evaporation method, or the like. Then, a mask is formed over the conductive film by a photolithography process. Next, part of the conductive film is etched with the use of the mask to form the gate electrode 202. After that, the mask is removed. Note that an electron beam lithography process may be used instead of the photolithography process.

For example, a 100-nm-thick tungsten film is formed by a sputtering method. Next, a mask is formed by a photolithography process, and the tungsten film is subjected to dry etching with the use of the mask to form the gate electrode 202. Note that an electron beam lithography process may be used instead of the photolithography process.

The gate insulating film 203 is formed by a sputtering method, a plasma CVD method, an evaporation method, or the like. In the case of forming a gallium oxide film as the gate insulating film 203, a metal organic chemical vapor deposition (MOCVD) method can be employed.

For example, the gate insulating film 203 is formed by stacking a 400-nm-thick silicon nitride film and a 50-nm-thick silicon oxynitride film by a plasma CVD method.

Next, as described in Embodiment 1, a zinc oxide film containing a single-crystal region is formed over the gate insulating film 203 and further, an In-M-Zn oxide film is formed using a c-axis-aligned In-M-Zn oxide target. The In-M-Zn oxide film contains a single-crystal region with an area of 5 μm² or more, preferably 1000 μm² or more. After that, the zinc oxide film and the In-M-Zn oxide film are etched, so that the oxide semiconductor layer 205 is formed over the gate insulating film 203 as illustrated in FIG. 12B.

Next, the pair of electrodes 208 and 209 is formed as illustrated in FIG. 12C. For example, a 50-nm-thick tungsten film, a 400-nm-thick aluminum film, and a 100-nm-thick titanium film are sequentially stacked by a sputtering method. Next, a mask is formed over the titanium film by a photolithography process and the tungsten film, the aluminum film, and the titanium film are dry-etched or wet-etched with the use of the mask to form the pair of electrodes 208 and 209. Note that an electron beam lithography process may be used instead of the photolithography process.

Next, as illustrated in FIG. 12D, the oxide insulating film 210 is formed over the oxide semiconductor layer 205 and the pair of electrodes 208 and 209. Next, the oxide insulating film 211 is formed over the oxide insulating film 210.

As the oxide insulating film 210, a silicon oxide film or a silicon oxynitride film can be formed under the following conditions: the substrate placed in a treatment chamber of a plasma CVD apparatus that is vacuum-evacuated is held at a temperature higher than or equal to 280° C. and lower than or equal to 400° C., the pressure is greater than or equal to 20 Pa and less than or equal to 250 Pa, preferably greater than or equal to 100 Pa and less than or equal to 250 Pa with introduction of a source gas into the treatment chamber, and a high-frequency power is supplied to an electrode provided in the treatment chamber.

A deposition gas containing silicon and an oxidation gas are preferably used as the source gas of the oxide insulating film 210. Typical examples of the deposition gas containing silicon include silane, disilane, trisilane, and silane fluoride. As the oxidation gas, oxygen, ozone, dinitrogen monoxide, nitrogen dioxide, and the like can be given as examples.

With the use of the above conditions, an oxide insulating film which is permeable to oxygen can be formed as the oxide insulating film 210. Further, by providing the oxide insulating film 210, damage to the oxide semiconductor layer 205 can be reduced in a step of forming the oxide insulating film 211 which is formed later. Consequently, the amount of oxygen vacancies in the oxide semiconductor film can be reduced.

Under the above film formation conditions, the bonding strength of silicon and oxygen becomes strong in the above substrate temperature range. Thus, as the oxide insulating film 210, a dense and hard oxide insulating film which is permeable to oxygen, typically, a silicon oxide film or a silicon oxynitride film of which etching using hydrofluoric acid of 0.5 wt % at 25° C. is performed at a rate of lower than or equal to 10 nm/min, preferably lower than or equal to 8 nm/min can be formed.

Here, as the oxide insulating film 210, a 50-nm-thick silicon oxynitride film is formed by a plasma CVD method in which silane with a flow rate of 30 sccm and dinitrogen monoxide with a flow rate of 4000 sccm are used as a source gas, the pressure in the treatment chamber is 200 Pa, the substrate temperature is 220° C., and a high-frequency power of 150 W is supplied to parallel-plate electrodes with the use of a 27.12 MHz high-frequency power source. Under the above conditions, a silicon oxynitride film which is permeable to oxygen can be formed.

As the oxide insulating film 211, a silicon oxide film or a silicon oxynitride film is formed under the following conditions: the substrate placed in a treatment chamber of the plasma CVD apparatus that is vacuum-evacuated is held at a temperature higher than or equal to 180° C. and lower than or equal to 280° C., preferably higher than or equal to 200° C. and lower than or equal to 240° C., the pressure is greater than or equal to 100 Pa and less than or equal to 250 Pa, preferably greater than or equal to 100 Pa and less than or equal to 200 Pa with introduction of a source gas into the treatment chamber, and a high-frequency power of greater than or equal to 0.17 W/cm² and less than or equal to 0.5 W/cm², preferably greater than or equal to 0.25 W/cm² and less than or equal to 0.35 W/cm² is supplied to an electrode provided in the treatment chamber.

A deposition gas containing silicon and an oxidation gas are preferably used as the source gas of the oxide insulating film 211. Typical examples of the deposition gas containing silicon include silane, disilane, trisilane, and silane fluoride. As the oxidation gas, oxygen, ozone, dinitrogen monoxide, nitrogen dioxide, and the like can be given as examples.

Here, as the oxide insulating film 211, a 400-nm-thick silicon oxynitride film is formed by a plasma CVD method in which silane with a flow rate of 200 sccm and dinitrogen monoxide with a flow rate of 4000 sccm are used as the source gas, the pressure in the treatment chamber is 200 Pa, the substrate temperature is 220° C., and the high-frequency power of 1500 W is supplied to the parallel-plate electrodes with the use of a 27.12 MHz high-frequency power source. Note that a plasma CVD apparatus used here is a parallel-plate plasma CVD apparatus in which the electrode area is 6000 cm², and the power per unit area (power density) into which the supplied power is converted is 0.25 W/cm².

Next, heat treatment is performed. The heat treatment is performed typically at a temperature higher than or equal to 250° C. and lower than the strain point of the substrate, preferably higher than or equal to 300° C. and lower than or equal to 550° C., more preferably higher than or equal to 350° C. and lower than or equal to 510° C.

An electric furnace, an RTA apparatus, or the like can be used for the heat treatment. With the use of an RTA apparatus, the heat treatment can be performed at a temperature higher than or equal to the strain point of the substrate if the heating time is short. Therefore, the heat treatment time can be shortened.

The heat treatment may be performed under an atmosphere of nitrogen, oxygen, ultra-dry air (air with a water content of 20 ppm or less, preferably 1 ppm or less, more preferably 10 ppb or less), or a rare gas (argon, helium, or the like). The atmosphere of nitrogen, oxygen, ultra-dry air, or a rare gas preferably does not contain hydrogen, water, and the like.

Note that as a heat treatment apparatus used for the heat treatment, the heating mechanism provided in the substrate heating chamber 125 described in Embodiment 1 can be used as appropriate.

By the heat treatment, part of oxygen contained in the oxide insulating film 211 can be moved to the oxide semiconductor layer 205, so that oxygen vacancies contained in the oxide semiconductor layer 205 can be filled. Consequently, the amount of oxygen vacancies contained in the oxide semiconductor layer 205 can be further reduced.

Further, in the case where water, hydrogen, or the like is contained in the oxide insulating film 210 and the oxide insulating film 211, when the nitride insulating film 212 having a function of blocking water, hydrogen, and the like is formed later and heat treatment is performed, water, hydrogen, or the like contained in the oxide insulating film 210 and the oxide insulating film 211 is moved to the oxide semiconductor layer 205, so that defects are generated in the oxide semiconductor layer 205. However, by the heating, water, hydrogen, or the like contained in the oxide insulating film 210 and the oxide insulating film 211 can be released; thus, variation in electrical characteristics of the transistor 200 can be reduced, and change in threshold voltage can be inhibited.

Note that when the oxide insulating film 211 is formed over the oxide insulating film 210 while being heated, oxygen can be moved to the oxide semiconductor layer 205 to compensate oxygen vacancies contained in the oxide semiconductor layer 205; thus, the heat treatment is not necessarily performed.

Next, the nitride insulating film 212 is formed by a sputtering method, a CVD method, or the like. Note that in the case where the nitride insulating film 212 is formed by a plasma CVD method, the substrate placed in the treatment chamber of the plasma CVD apparatus that is vacuum-evacuated is preferably held at a temperature higher than or equal to 300° C. and lower than or equal to 400° C., more preferably higher than or equal to 320° C. and lower than or equal to 370° C., so that a dense nitride insulating film can be formed.

For example, in the treatment chamber of a plasma CVD apparatus, a 50-nm-thick silicon nitride film is formed by a plasma CVD method in which silane with a flow rate of 50 sccm, nitrogen with a flow rate of 5000 sccm, and ammonia with a flow rate of 100 sccm are used as the source gas, the pressure in the treatment chamber is 100 Pa, the substrate temperature is 350° C., and high-frequency power of 1000 W is supplied to parallel-plate electrodes with the use of a 27.12 MHz high-frequency power source.

By the above-described steps, the protective film 213 including the oxide insulating film 210, the oxide insulating film 211, and the nitride insulating film 212 can be formed.

Next, heat treatment may be performed. The heat treatment is performed typically at a temperature higher than or equal to 300° C. and lower than or equal to 400° C., preferably higher than or equal to 320° C. and lower than or equal to 370° C.

Through the above-described process, the transistor 200 can be manufactured.

From the above, as for a semiconductor device including an oxide semiconductor film, a semiconductor device in which the amount of defects is reduced can be obtained. Further, as for a semiconductor device including an oxide semiconductor film, a semiconductor device with improved electrical characteristics can be obtained.

Note that the structures, methods, and the like described in this embodiment can be used as appropriate in combination with any of the structures, methods, and the like described in other embodiments and modification examples thereof.

### Embodiment 3

In this embodiment, a semiconductor device having a transistor in which the amount of defects in an oxide semiconductor film can be further reduced as compared to Embodiment 2 is described with reference to drawings. The transistor described in this embodiment is different from that in Embodiment 2 in that a multilayer film having an oxide semiconductor film and oxide in contact with the oxide semiconductor film is included.

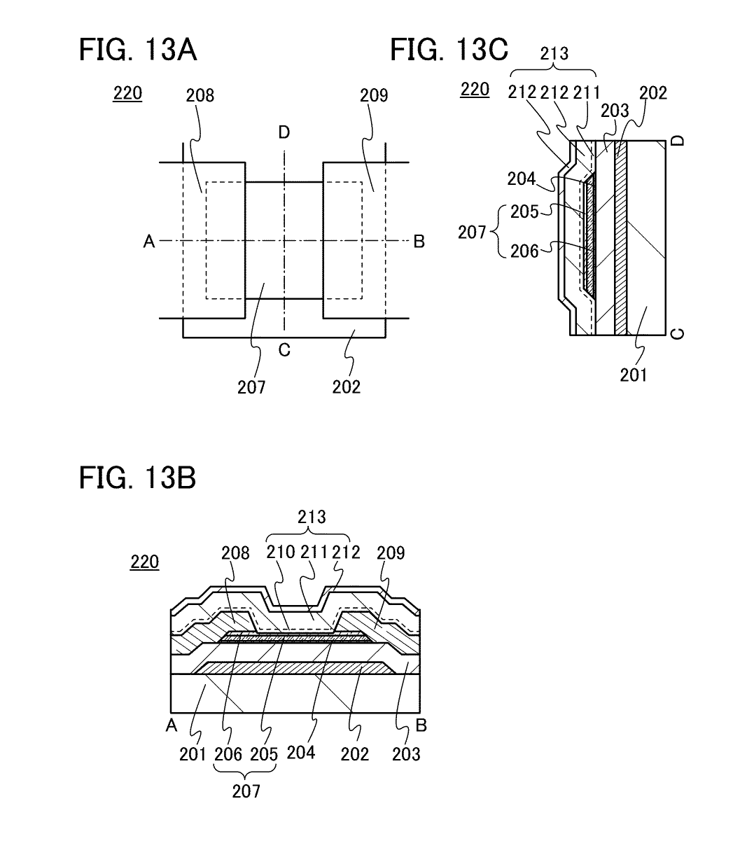

FIGS. 13A to 13C are a top view and cross-sectional views of a transistor 220 included in the semiconductor device. FIG. 13A is a top view of the transistor 220, FIG. 13B is a cross-sectional view taken along dashed-dotted line A-B in FIG. 13A, and FIG. 13C is a cross-sectional view taken along dashed-dotted line C-D in FIG. 13A. Note that in FIG. 13A, some components of the transistor 220 (e.g., the substrate 201, the gate insulating film 203, the oxide insulating film 210, the oxide insulating film 211, the nitride insulating film 212, and the like) are not illustrated for clarity.

The transistor 220 shown in FIGS. 13A to 13C includes an oxide stack 207 which is over the gate insulating film 203 and overlaps with the gate electrode 202, the zinc oxide layer 204 in close contact with the bottom surface of the oxide semiconductor layer 205, and the pair of electrodes 208 and 209 in contact with the oxide stack 207. Furthermore, the protective film 213 including the oxide insulating film 210, the oxide insulating film 211, and the nitride insulating film 212 is formed over the gate insulating film 203, the oxide stack 207, and the pair of electrodes 208 and 209.

In the transistor 220 described in this embodiment, the oxide stack 207 includes the oxide semiconductor layer 205 and the oxide layer 206. That is, the oxide stack 207 has a two-layer structure. Further, part of the oxide semiconductor layer 205 serves as a channel region. Furthermore, the oxide insulating film 210 is formed in contact with the oxide stack 207, and the oxide insulating film 211 is formed in contact with the oxide insulating film 210. That is, the oxide layer 206 is provided between the oxide semiconductor layer 205 and the oxide insulating film 210.

The oxide layer 206 is an oxide film containing one or more elements which form the oxide semiconductor layer 205. Since the oxide layer 206 contains one or more elements which form the oxide semiconductor layer 205, interface scattering is unlikely to occur at the interface between the oxide semiconductor layer 205 and the oxide layer 206. Thus, the transistor can have high field-effect mobility because the movement of carriers is not hindered at the interface.

The oxide layer 206 is typically In—Ga oxide, In—Zn oxide, or In-M-Zn oxide (M represents Al, Ti, Ga, Y, Zr, La, Ce, Nd, or Hf). The energy at the conduction band bottom of the oxide layer 206 is closer to a vacuum level than that of the oxide semiconductor layer 205 is, and typically, the difference between the energy at the conduction band bottom of the oxide layer 206 and the energy at the conduction band bottom of the oxide semiconductor layer 205 is any one of 0.05 eV or more, 0.07 eV or more, 0.1 eV or more, and 0.15 eV or more, and any one of 2 eV or less, 1 eV or less, 0.5 eV or less, and 0.4 eV or less. That is, the difference between the electron affinity of the oxide layer 206 and the electron affinity of the oxide semiconductor layer 205 is any one of 0.05 eV or more, 0.07 eV or more, 0.1 eV or more, and 0.15 eV or more, and any one of 2 eV or less, 1 eV or less, 0.5 eV or less, and 0.4 eV or less.

The oxide layer 206 preferably contains In because carrier mobility (electron mobility) can be increased.

When the oxide layer 206 contains a higher proportion of Al, Ti, Ga, Y, Zr, La, Ce, Nd, or Hf in an atomic ratio than the proportion of In in an atomic ratio, any of the following effects may be obtained:

(1) the energy gap of the oxide layer 206 is widened;

(2) the electron affinity of the oxide layer 206 decreases;

(3) an impurity from the outside is blocked;

(4) the insulating property of the oxide layer 206 increases as compared to the oxide semiconductor layer 205; and

(5) oxygen vacancies are less likely to be generated because the metal element has a high bonding strength to oxygen.

In the case where the oxide layer 206 is an In-M-Zn oxide film (M represents Al, Ti, Ga, Y, Zr, La, Ce, Nd, or Hf), the atomic ratio of metal elements of a sputtering target used for forming the In-M-Zn oxide film preferably satisfies M>In and Zn>M As the atomic ratio of metal elements of such a sputtering target, indium:gallium:zinc=1:3:4, indium:gallium:zinc=1:3:5, indium:gallium:zinc=1:3:6, indium:gallium:zinc=1:3:7, indium:gallium:zinc=1:3:8, indium:gallium:zinc=1:3:9, indium:gallium:zinc=1:3:10, indium:gallium:zinc=1:6:7, indium:gallium:zinc=1:6:8, indium:gallium:zinc=1:6:9, or indium:gallium:zinc=1:6:10 is preferable.

In the case where the oxide layer 206 is In-M-Zn oxide, the atomic ratio of In and M is preferably as follows: the percentage of In is lower than 50% (i.e., the percentage of M is higher than or equal to 50%), preferably the percentage of In is lower than 25% (i.e., the percentage of M is higher than or equal to 75%).

Further, in the case where each of the oxide semiconductor layer 205 and the oxide layer 206 is In-M-Zn oxide (M represents Al, Ti, Ga, Y, Zr, La, Ce, Nd, or Hf), the proportion of M atoms (M represents Al, Ti, Ga, Y, Zr, La, Ce, Nd, or Hf) in the oxide layer 206 is higher than that in the oxide semiconductor layer 205. Typically, the proportion of M in the oxide layer 206 is 1.5 or more times, twice or more, or three or more times as high as that in the oxide semiconductor layer 205.

Furthermore, in the case where each of the oxide semiconductor layer 205 and the oxide layer 206 is an In-M-Zn oxide (M represents Al, Ti, Ga, Y, Zr, La, Ce, Nd, or Hf), when In:M:Zn=x₁:y₁:z₁ [atomic ratio] is satisfied in the oxide layer 206 and In:M:Zn=x₂:y₂:z₂ [atomic ratio] is satisfied in the oxide semiconductor layer 205, y₁/x₁ is higher than y₂/x₂. It is preferable that y₁/x₁ be 1.5 or more times as high as y₂/x₂. It is further preferable that y₁/x₁ be twice or more as high as y₂/x₂. It is still further preferable that y₁/x₁ be three or more times as high as y₂/x₂. In this case, it is preferable that in the oxide semiconductor film, y₂ be higher than or equal to x₂ because a transistor including the oxide semiconductor film can have stable electrical characteristics. However, when y_{z} is larger than or equal to three or more times x₂, the field-effect mobility of the transistor including the oxide semiconductor film is reduced. Accordingly, y₂ is preferably smaller than or equal to x₂.

The oxide layer 206 is preferably formed using the sputtering target described in Embodiment 1, and typically, a sputtering target with an atomic ratio of In:M:Zn=1:3:3.05 to 1:3:10 or a sputtering target with an atomic ratio of In:M:Zn=1:6:6.05 to 1:6:10 can be used. Note that the atomic ratio of M/In and the atomic ratio of Zn/In in the oxide semiconductor layer 205 formed using such a sputtering target are lower than those in the sputtering target. The atomic ratio of Zn to M (Zn/M) in an In—Ga—Zn oxide film is higher than or equal to 0.5.

The oxide layer 206 also serves as a film which relieves damage to the oxide semiconductor layer 205 at the time of forming the oxide insulating film 211 later. Consequently, the amount of oxygen vacancies in the oxide semiconductor layer 205 can be reduced. In addition, by forming the oxide layer 206, mixing of a constituent element of an insulating film, e.g., the oxide insulating film, formed over the oxide semiconductor layer 205 to the oxide semiconductor layer 205 can be inhibited.

The thickness of the oxide layer 206 is greater than or equal to 3 nm and less than or equal to 100 nm, preferably greater than or equal to 3 nm and less than or equal to 50 nm.

Further, the oxide layer 206, like the oxide semiconductor layer 205, contains a single-crystal region with an area of 5 μm² or more, preferably 1000 μm² or more.

In the transistor 220 in this embodiment, the oxide layer 205 is provided between the oxide semiconductor layer 206 and the oxide insulating film 210. Hence, if trap states are formed between the oxide layer 206 and the oxide insulating film 210 owing to impurities and defects, electrons flowing in the oxide semiconductor layer 205 are less likely to be captured by the trap states because there is a distance between the trap states and the oxide semiconductor layer 205. Accordingly, the amount of on-state current of the transistor can be increased, and the field-effect mobility can be increased. When electrons are captured by the trap states, the electrons become negative fixed charges. As a result, a threshold voltage of the transistor changes. However, by the distance between the oxide semiconductor layer 205 and the trap states, capture of the electrons by the trap states can be reduced, and accordingly change in the threshold voltage can be reduced.

Further, impurities from the outside can be blocked by the oxide layer 206, and accordingly, the amount of impurities which move from the outside to the oxide semiconductor layer 205 can be reduced. Further, an oxygen vacancy is less likely to be formed in the oxide layer 206. Consequently, the impurity concentration and the amount of oxygen vacancies in the oxide semiconductor layer 205 can be reduced.

Note that the oxide semiconductor layer 205 and the oxide layer 206 are not formed by simply stacking each film, but are formed to form a continuous junction (here, in particular, a structure in which the energy of the bottom of the conduction band is changed continuously between the films). In other words, a stacked-layer structure in which there exists no impurity which forms a defect level such as a trap center or a recombination center at each interface is provided. If an impurity exists between the oxide semiconductor layer 205 and the oxide layer 206 which are stacked, a continuity of the energy band is damaged, and the carrier is captured or recombined at the interface and then disappears.

In order to form such a continuous junction it is necessary to form films continuously without being exposed to the air, with use of the multi-chamber deposition apparatus including a load lock chamber which is described in Embodiment 1.

Note that the structures, methods, and the like described in this embodiment can be used as appropriate in combination with any of the structures, methods, and the like described in other embodiments and modification examples thereof.

### Embodiment 4

In this embodiment, a method for manufacturing a top-gate transistor will be described.

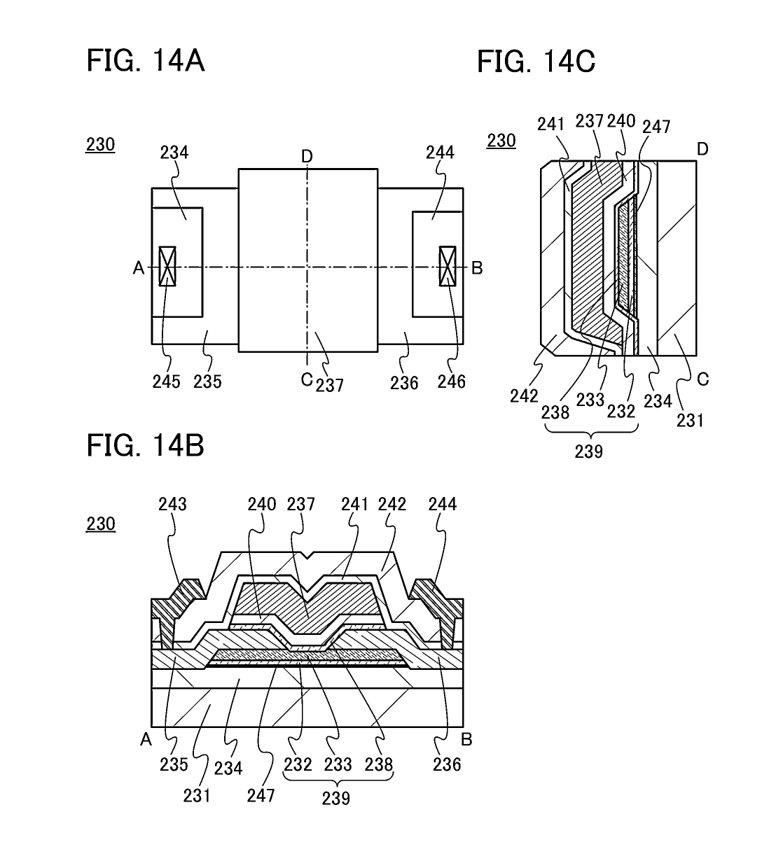

FIGS. 14A to 14C are a top view and cross-sectional views of a transistor 230 of a semiconductor device. FIG. 14A is a top view of the transistor 230, FIG. 14B is a cross-sectional view taken along dashed-dotted line A-B in FIG. 14A, and FIG. 14C is a cross-sectional view taken along dashed-dotted line C-D in FIG. 14A. Note that in FIG. 14A, some components of the transistor 230 (e.g., a substrate 231, a third oxide semiconductor layer 238, and a gate insulating layer 240), an insulating film 241, an insulating film 242, and the like are not illustrated for clarity.

The transistor 230 illustrated in FIGS. 14A to 14C includes an oxide insulating film 234 over the substrate 231, a zinc oxide layer 247 over the oxide insulating film 234, a first oxide semiconductor layer 232 over the zinc oxide layer 247, a second oxide semiconductor layer 233 over the first oxide semiconductor layer 232, a pair of electrodes 235 and 236 in contact with the second oxide semiconductor layer 233, the third oxide semiconductor layer 238 in contact with the oxide insulating film 234, the second oxide semiconductor layer 233, and the pair of electrodes 235 and 236, the gate insulating layer 240 in contact with the third oxide semiconductor layer 238, and a gate electrode 237 overlapping with the second oxide semiconductor layer 233 with the gate insulating layer 240 provided therebetween. Note that the first oxide semiconductor layer 232, the second oxide semiconductor layer 233, and the third oxide semiconductor layer 238 are collectively referred to as an oxide semiconductor stack 239. The insulating film 241 covering the gate insulating layer 240 and the gate electrode 237 and the insulating film 242 covering the insulating film 241 may be provided. In openings 245 and 246 in the gate insulating layer 240, the insulating film 241, and the insulating film 242, wirings 243 and 244 in contact with the pair of electrodes 235 and 236 may be provided.

Components of the transistor 230 are described below.

Examples of the oxide insulating film 234 serving as a base insulating film include silicon oxide, silicon oxynitride, silicon nitride, silicon nitride oxide, gallium oxide, hafnium oxide, yttrium oxide, aluminum oxide, aluminum oxynitride, and the like. Note that when silicon nitride, gallium oxide, hafnium oxide, yttrium oxide, aluminum oxide, or the like is used for the oxide insulating film 234 serving as a base insulating film, it is possible to suppress diffusion of impurities such as alkali metal, water, and hydrogen into the oxide semiconductor film from the substrate 231.

The oxide insulating film 234 can be formed using an oxide insulating film which contains oxygen at a higher proportion than the stoichiometric composition. In other words, an oxide insulating film from which part of oxygen is released by heating can be formed. With use of such a film, the oxygen in the oxide insulating film 234 is transferred to the second oxide semiconductor layer 233; thus, the density of defect states at the interface between the oxide insulating film 234 and the first oxide semiconductor layer 232 can be reduced, and oxygen vacancies can be further reduced by filling oxygen vacancies in the second oxide semiconductor layer 233.

Embodiment 1 can be referred to for the zinc oxide layer 247.

For each of the first oxide semiconductor layer 232, the second oxide semiconductor layer 233, and the third oxide semiconductor layer 238 included in the oxide semiconductor stack 239, Embodiment 1 or FIG. 3F can be referred to. The average thickness of the oxide semiconductor stack 239 is set to less than or equal to 0.5 μm, preferably greater than or equal to 5 nm and less than or equal to 500 nm.

The thickness of the second oxide semiconductor layer 233 is greater than or equal to 3 nm and less than or equal to 200 nm, preferably greater than or equal to 3 nm and less than or equal to 100 nm, more preferably greater than or equal to 3 nm and less than or equal to 50 nm.

Each of the first oxide semiconductor layer 232 and the third oxide semiconductor layer 238 has a thickness greater than or equal to 0.3 nm and less than or equal to 200 nm, preferably greater than or equal to 3 nm and less than or equal to 100 nm, more preferably greater than or equal to 3 nm and less than or equal to 50 nm. Note that it is preferable that the first oxide semiconductor layer 232 have a smaller thickness than that of the second oxide semiconductor layer 233. Further, it is preferable that the third oxide semiconductor layer 238 have a smaller thickness than that of the second oxide semiconductor layer 233.

When the first oxide semiconductor layer 232 is thin, electrons are captured at the interface between the first oxide semiconductor layer 232 and the second oxide semiconductor layer 233, so that the on-state current of the transistor is decreased. In contrast, when the first oxide semiconductor layer 232 is thick, the amount of oxygen which moves from the oxide insulating film 234 to the second oxide semiconductor layer 233 is reduced; thus, it becomes difficult to reduce the amount of oxygen vacancies and the amount of hydrogen in the second oxide semiconductor layer 233. Therefore, it is preferable that the first oxide semiconductor layer 232 have a thickness greater than or equal to 20 nm and less than or equal to 200 nm, which is smaller than the second oxide semiconductor layer 233.

The first oxide semiconductor layer 232, the second oxide semiconductor layer 233, and the third oxide semiconductor layer 238 are formed over the zinc oxide layer 247 including a single-crystal region according to the deposition model described in Embodiment 1. Thus, the first oxide semiconductor layer 232 and the second oxide semiconductor layer 233 each include a single-crystal region with an area of 5 μm² or more, preferably 1000 μm² or more. The third oxide semiconductor layer 238 also includes a single-crystal region with an area of 5 μm² or more, preferably 1000 μm² or more.

As the insulating films 241 and 242, the oxide insulating films 210 and 211 described in Embodiment 2 can be used as appropriate. Note that an aluminum oxide film, a hafnium oxide film, an yttrium oxide film, or the like which can be used as an oxygen blocking film can be used as the insulating film 241.

Further, in the case where side surfaces of the third oxide semiconductor layer 238, the gate insulating layer 240, and the gate electrode 237 are substantially aligned with each other and the insulating film 241 is in contact with surfaces of the pair of electrodes 235 and 236, the third oxide semiconductor layer 238, the gate insulating layer 240, and the gate electrode 237, release of oxygen from the oxide semiconductor stack 239 in later heat treatment can be reduced. Thus, variation in electrical characteristics of the transistor can be reduced, and change in threshold voltage can be inhibited.

Although a stacked-layer structure of the insulating film 241 and the insulating film 242 is used here as an example, a single-layer structure may be used.

For the wirings 243 and 244, a material similar to that of the pair of electrodes 235 and 236 can be used as appropriate.

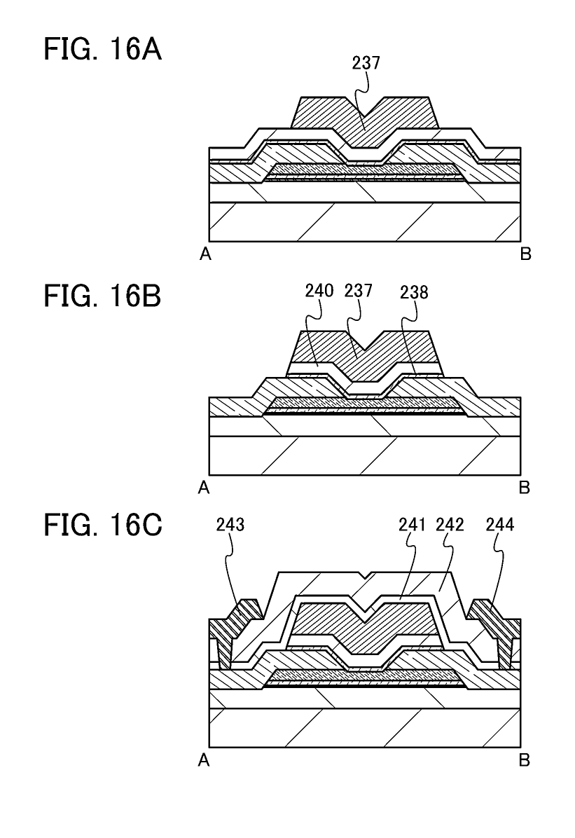

In the transistor in this embodiment, an edge portion of the third oxide semiconductor layer 238 and an edge portion of the gate insulating layer 240 are substantially aligned with an edge portion of the gate electrode 237. The third oxide semiconductor layer 238 and the gate insulating layer 240 having such shapes can be formed without an increase in the number of masks by forming the gate electrode 237 in FIG. 16A and etching the third oxide semiconductor film 252 and the gate insulating film 253.

In the transistor 230, an etching residue generated at the time of forming the gate electrode 237 can be removed when the third oxide semiconductor layer 238 and the gate insulating layer 240 are formed; thus, leakage current generated between the gate electrode 237 and the wirings 243 and 244 can be reduced.

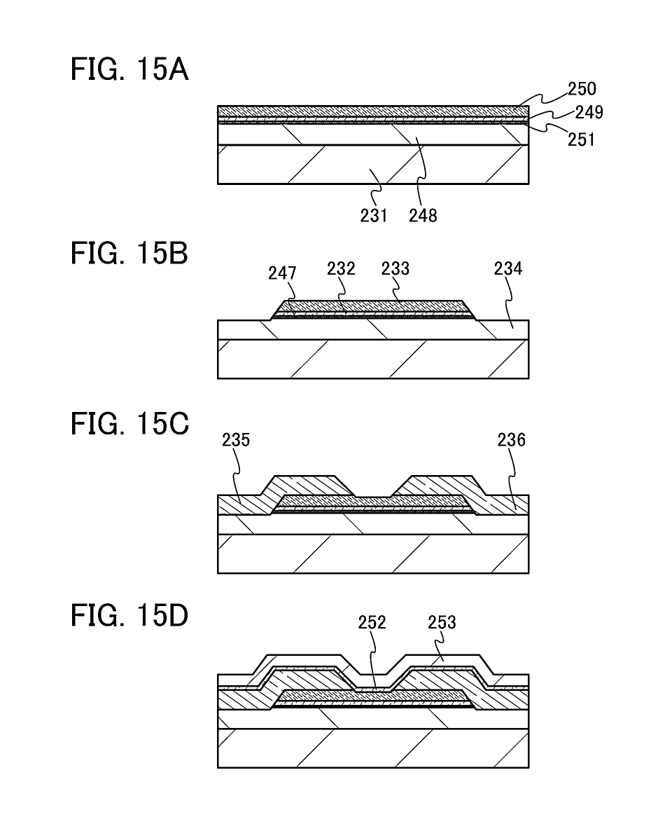

Next, a method for manufacturing the transistor 230 will be described with reference to FIGS. 15A to 15D and FIGS. 16A to 16C.

As illustrated in FIG. 15A, an oxide insulating film 248 which is a base insulating film is formed over the substrate 231, and a zinc oxide film 251, a first oxide semiconductor film 249, and a second oxide semiconductor film 250 are formed over the oxide insulating film 248.

For example, a glass substrate is used as the substrate 231.

The oxide insulating film 248 can be formed by a sputtering method or a CVD method.

In the case where an oxide insulating film containing oxygen in excess of the stoichiometric composition is formed as the oxide insulating film 248 in a manner similar to that of the oxide insulating film 211 described in Embodiment 2, the oxide insulating film can be formed by a CVD method, a sputtering method, or the like. Alternatively, after the oxide insulating film is formed by a CVD method, a sputtering method, or the like, oxygen may be added to the oxide insulating film by an ion implantation method, an ion doping method, plasma treatment, or the like.

For example, a 300-nm-thick silicon oxide film formed by a sputtering method is used as the oxide insulating film 248.

The zinc oxide film 251, the first oxide semiconductor film 249, and the second oxide semiconductor film 250 can be formed by the method described in Embodiment 1. The first oxide semiconductor film 249 and the second oxide semiconductor film 250 are deposited over the zinc oxide film 251 including a single-crystal region. Thus, the first oxide semiconductor film 249 and the second oxide semiconductor film 250 each include a single-crystal region with an area of 5 μm² or more, preferably 1000 μm² or more.

For example, a 50-nm-thick In—Ga—Zn oxide film is formed by a sputtering method using a sputtering target having an atomic ratio of indium:gallium:zinc=1:3:4 as the first oxide semiconductor film 249. Further, a 20-nm-thick In—Ga—Zn oxide film is formed by a sputtering method using a sputtering target having an atomic ratio of indium:gallium:zinc=5:5:6 as the second oxide semiconductor film 250.

Next, a mask is formed over the second oxide semiconductor film 250 by a photolithography process or an electron beam lithography process and then the zinc oxide film 251, the first oxide semiconductor film 249, and the second oxide semiconductor film 250 are each partly etched using the mask, so that the first oxide semiconductor layer 232 and the second oxide semiconductor layer 233 are formed as illustrated in FIG. 15B. After that, the mask is removed. Note that in the etching step, the oxide insulating film 248 is partly etched in some cases. For example, the oxide insulating film 248 which is partly etched is referred to as the oxide insulating film 234.

Next, as illustrated in FIG. 15C, the pair of electrodes 235 and 236 is formed over the second oxide semiconductor layer 233. The distance between the pair of electrodes 235 and 236 may be less than or equal to 30 nm. At this time, an electron beam lithography process may be employed.

Next, as illustrated in FIG. 15D, the third oxide semiconductor film 252 is formed over the second oxide semiconductor layer 233 and the pair of electrodes 235 and 236, and the gate insulating film 253 is formed over the third oxide semiconductor film 252.

The third oxide semiconductor film 252 can be formed in a manner similar to that of the first oxide semiconductor layer 232. In this case, the first oxide semiconductor layer 232 and the second oxide semiconductor layer 233 includes a single-crystal region with an area of 5 μm² or more, preferably 1000 μm² or more, and thus, the third oxide semiconductor film 252 which is formed in close contact with the second oxide semiconductor layer 233 also includes a single-crystal region with an area of 5 μm² or more, preferably 1000 μm² or more.

For example, a 5-nm-thick In—Ga—Zn oxide film is formed as the third oxide semiconductor film 252 by a sputtering method using a sputtering target with an atomic ratio of indium:gallium:zinc=1:3:4.

Then, as illustrated in FIG. 16A, the gate electrode 237 is formed in a region which is over the gate insulating film 253 and overlaps with the second oxide semiconductor layer 233.

Next, as illustrated in FIG. 16B, the third oxide semiconductor film 252 and the gate insulating film 253 are etched using the gate electrode 237 as a mask to form the third oxide semiconductor layer 238 and the gate insulating layer 240. An edge portion of the third oxide semiconductor layer 238 and an edge portion of the gate insulating layer 240 are substantially aligned with an edge portion of the gate electrode 237.

In the transistor 230, an etching residue generated at the time of forming the gate electrode 237 can be removed when the third oxide semiconductor layer 238 and the gate insulating layer 240 are formed; thus, leakage current generated between the gate electrode 237 and the wirings 243 and 244 which are formed later can be reduced.

Next, as illustrated in FIG. 16C, the insulating film 241 and the insulating film 242 are stacked in this order over the pair of electrodes 235 and 236 and the gate electrode 237. Next, heat treatment is performed. After openings are formed in the insulating film 241 and the insulating film 242, the wirings 243 and 244 are formed.

The insulating film 241 and the insulating film 242 can be formed by a sputtering method, a CVD method, or the like as appropriate. When an oxygen blocking film is used as the insulating film 241, release of oxygen from the oxide semiconductor stack 239 in later heat treatment can be reduced. Thus, variation in electrical characteristics of the transistor can be reduced, and change in threshold voltage can be inhibited.

For example, a 300-nm-thick silicon oxynitride film is formed by a plasma CVD method as the insulating film 241, and a 50-nm-thick silicon nitride film is formed by a sputtering method as the insulating film 242. Further, heat treatment is performed at 350° C. for 1 hour in an atmosphere of nitrogen and oxygen.

Through the above steps, a transistor having excellent electrical characteristics can be manufactured. In addition, a highly reliable transistor in which a variation in electrical characteristics with time or a variation in electrical characteristics due to a stress test is small can be manufactured.

Note that the structures, methods, and the like described in this embodiment can be used as appropriate in combination with any of the structures, methods, and the like described in other embodiments and modification examples thereof.

### Embodiment 5

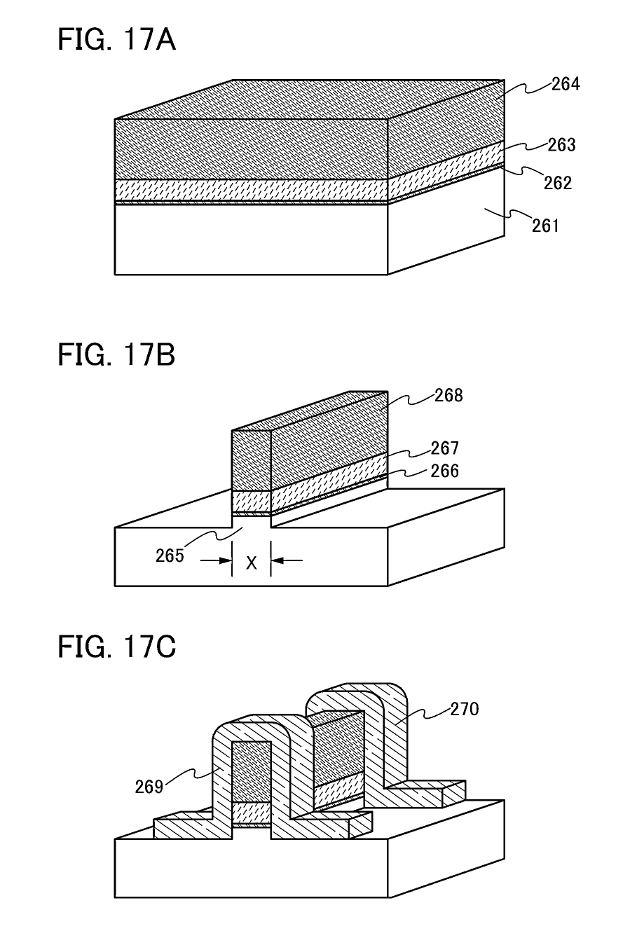

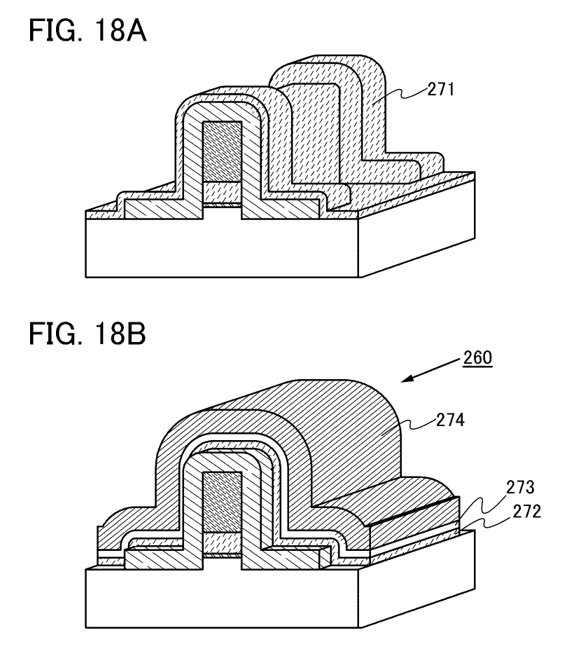

In this embodiment, an example where the oxide semiconductor including a single-crystal region described in Embodiment 1 is used in a FIN-type transistor is described with reference to FIGS. 17A to 17C and FIGS. 18A and 18B.

### <FIG. 17A>

A zinc oxide film 262, a first oxide semiconductor film 263, and a second oxide semiconductor film 264 are deposited over an amorphous insulating film 261 by the method described in Embodiment 1. As described in Embodiment 1, each of the first oxide semiconductor film 263 and the second oxide semiconductor film 264 includes an island-shaped single-crystal thin film which includes a single-crystal region and has an area of 5 μm² or more, preferably 1000 μm² or more and is a thin film extremely close to a single crystal including such an island-shaped single-crystal thin film at a proportion of 80% or higher, preferably 95% or higher in the film.

### <FIG. 17B>

The zinc oxide film 262, the first oxide semiconductor film 263, and the second oxide semiconductor film 264 are etched, so that a zinc oxide layer 266, a first oxide semiconductor layer 267, and a second oxide semiconductor layer 268 each having a stripe shape are formed. At this time, the amorphous insulating film 261 is also etched, so that a projected portion 265 is formed in some cases. Further, the width X of each of the zinc oxide layer 266, the first oxide semiconductor layer 267, the second oxide semiconductor layer 268, and the projected portion 265 is preferably 10 nm to 30 nm

### <FIG. 17C>

A first conductive film is formed over the zinc oxide layer 266, the first oxide semiconductor layer 267, and the second oxide semiconductor layer 268 and is selectively removed, so that a pair of electrodes 269 and 270 is formed. One of the electrodes 269 and 270 functions as a source electrode, and the other functions as a drain electrode.

### <FIG. 18A>

A third oxide semiconductor film 271 is formed over the zinc oxide layer 266, the first oxide semiconductor layer 267, the second oxide semiconductor layer 268, the electrode 269, and the electrode 270.

### <FIG. 18B>

An insulating film and a second conductive film are formed over the third oxide semiconductor film 271, and the third oxide semiconductor film 271, the insulating film, and the second conductive film are selectively removed. As a result, a gate electrode 274, and a gate insulating layer 273 and a third oxide semiconductor layer 272 each of which has substantially the same shape as that of the gate electrode 274 can be obtained. Through the above steps, a FIN-type transistor 260 is manufactured.

Note that the structures, methods, and the like described in this embodiment can be used as appropriate in combination with any of the structures, methods, and the like described in other embodiments and modification examples thereof.

### Embodiment 6

In this embodiment, a semiconductor device manufactured by applying the metal oxide which is a single crystal or substantially equivalent to a single crystal described in any of Embodiments 1 to 5 to a semiconductor film of a transistor is described. A transistor including an oxide semiconductor film which is a single crystal or substantially equivalent to a single crystal has high reliability and small variation in electrical characteristics due to irradiation with visible light or ultraviolet light and thus can be preferably used for a variety of semiconductor devices.

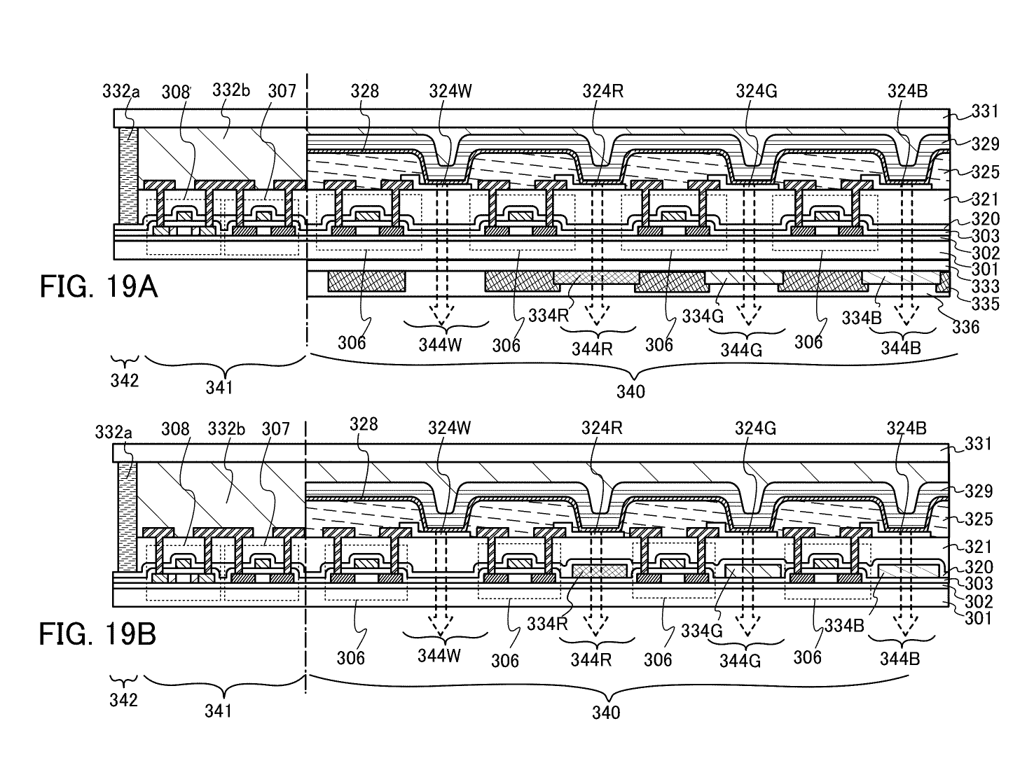

First, an active matrix light-emitting device which includes a transistor including an oxide semiconductor film which is a single crystal or substantially equivalent to a single crystal is described with reference to FIGS. 19A and 19B.

FIGS. 19A and 19B show examples of a light-emitting device which realizes full color display with the use of a coloring layer and the like. In FIG. 19A, transistors 306, 307, and 308 including oxide semiconductor films each of which is a single crystal or substantially equivalent to a single crystal, a substrate 301, a base insulating film 302, an insulating film 303, a first interlayer insulating film 320, a second interlayer insulating film 321, a peripheral portion 342, a pixel portion 340, a driver circuit portion 341, first electrodes 324W, 324R, 324G, and 324B of light-emitting elements, a partition wall 325, an EL layer 328, a second electrode 329 of the light-emitting elements, a sealing substrate 331, a sealant 332a, a sealant 332b, and the like are illustrated. The sealant 332b can be mixed with a desiccant. Further, coloring layers (a red coloring layer 334R, a green coloring layer 334G, and a blue coloring layer 334B) are provided on a transparent base material 333. Further, a black layer (a black matrix) 335 may be additionally provided. The transparent base material 333 provided with the coloring layers and the black layer is positioned and fixed to the substrate 301. Note that the coloring layers and the black layer are covered with an overcoat layer 336. In this embodiment, light emitted from some of the light-emitting layers does not pass through the coloring layers, while light emitted from the others of the light-emitting layers passes through the coloring layers. Since light which does not pass through the coloring layers is white and light which passes through any one of the coloring layers is red, blue, or green, an image can be displayed using pixels of the four colors.

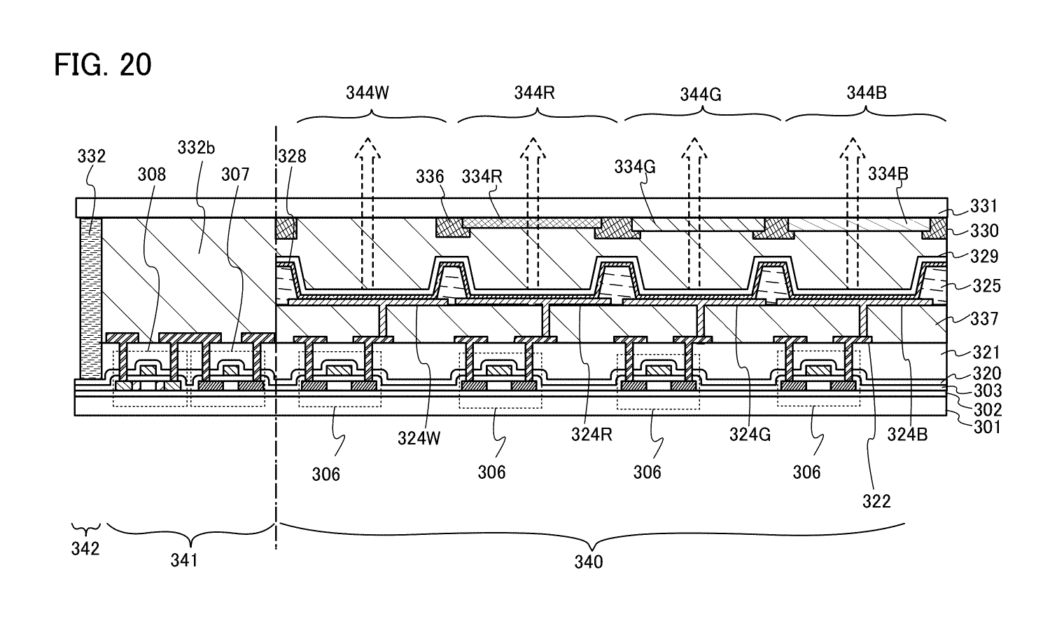

The above-described light-emitting device is a light-emitting device having a structure in which light is extracted from the substrate 301 side where the TFTs are formed (a bottom emission structure), but may be a light-emitting device having a structure in which light is extracted from the sealing substrate 331 side (a top emission structure). FIG. 20 is a cross-sectional view of a light-emitting device having a top emission structure. In this case, a substrate which does not transmit light can be used as the substrate 301. The process up to the step of forming a connection electrode which connects the TFT and the anode of the light-emitting element is performed in a manner similar to that of the light-emitting device having a bottom emission structure. Then, a third interlayer insulating film 337 is formed to cover an electrode 322. The third interlayer insulating film 337 may have a planarization function. The third interlayer insulating film 337 can be formed using a material similar to that of the second interlayer insulating film 321, and can alternatively be formed using any other known material. In addition, a space between the light-emitting elements and the sealing substrate 331 is filled with the sealant 332b, so that the light extraction efficiency can be improved.

The first electrodes 324W, 324R, 324G, and 324B of the light-emitting elements each serve as an anode here, but may serve as a cathode. Further, in the case of a light-emitting device having a top emission structure as illustrated in FIG. 20, the first electrodes are preferably reflective electrodes. The EL layer 328 is formed to have a structure with which white light emission can be obtained. As the structure with which white light emission can be obtained, in the case where two EL layers are used, a structure with which blue light is obtained from a light-emitting layer in one of the EL layers and orange light is obtained from a light-emitting layer of the other of the EL layers; a structure in which blue light is obtained from a light-emitting layer of one of the EL layers and red light and green light are obtained from a light-emitting layer of the other of the EL layers; and the like can be given. Further, in the case where three EL layers are used, red light, green light, and blue light are obtained from respective light-emitting layers, so that a light-emitting element which emits white light can be obtained.

The coloring layers are each provided in a light path through which light from the light-emitting element passes to the outside of the light-emitting device. In the case of the light-emitting device having a bottom emission structure as illustrated in FIG. 19A, the coloring layers 334R, 334G, and 334B can be provided on the transparent base material 333 and then fixed to the substrate 301. The coloring layers may be provided between the insulating film 303 and the first interlayer insulating film 320 as illustrated in FIG. 19B. In the case of a light-emitting device having a top emission structure as illustrated in FIG. 20, sealing can be performed with the sealing substrate 331 on which the coloring layers (the red coloring layer 334R, the green coloring layer 334G, and the blue coloring layer 334B) are provided. The sealing substrate 331 may be provided with the black layer (the black matrix) 335 which is positioned between pixels. The coloring layers (the red coloring layer 334R, the green coloring layer 334G, and the blue coloring layer 334B) and the black layer (the black matrix) may be covered with the overcoat layer 336. Note that a light-transmitting substrate is used as the sealing substrate 331.

When voltage is applied between the pair of electrodes of the thus obtained light-emitting element, a white light-emitting region 344W can be obtained. In addition, by using the coloring layers, a red light-emitting region 344R, a blue light-emitting region 344B, and a green light-emitting region 344G can be obtained. The light-emitting device in this embodiment includes the oxide semiconductor which is a single crystal or substantially equivalent to a single crystal described in any one of Embodiments 1 to 5 or a transistor including the oxide semiconductor; thus, a highly reliable light-emitting device can be obtained.

Further, although an example in which full color display is performed using four colors of red, green, blue, and white is shown here, there is no particular limitation and full color display using three colors of red, green, and blue may be performed.

Next, examples of electronic devices each of which includes, as a part thereof, the oxide semiconductor which is a single crystal or substantially equivalent to a single crystal described in any one of Embodiments 1 to 5 or a transistor including the oxide semiconductor are described.

Examples of the electronic device to which the above transistor is applied include television devices (also referred to as a TV or television receivers), monitors for computers and the like, cameras such as digital cameras and digital video cameras, digital photo frames, mobile phones (also referred to as cell phones or mobile phone devices), portable game machines, portable information terminals, audio reproducing devices, large game machines such as pachinko machines, and the like. Specific examples of these electronic devices are given below.

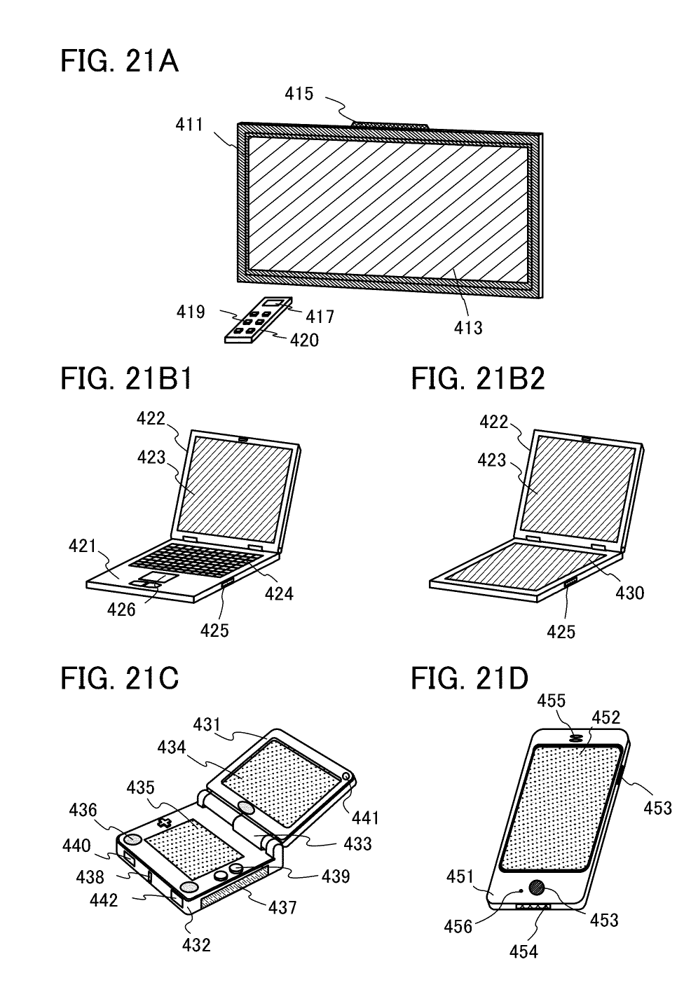

FIG. 21A illustrates an example of a television device. In the television device, a display portion 413 is incorporated in a housing 411. In addition, here, the housing 411 is supported to a wall by a fixing member 415. Images can be displayed on the display portion 413, and the display portion 413 includes the oxide semiconductor which is a single crystal or substantially equivalent to a single crystal described in any one of Embodiments 1 to 5 or a transistor including the oxide semiconductor. Thus, the television device can be a highly reliable television device.

Operation of the television device can be performed with an operation switch of the housing 411 or a separate remote controller 420. With operation keys 419 of the remote controller 420, channels and volume can be controlled and images displayed on the display portion 413 can be controlled. Furthermore, the remote controller 420 may be provided with a display portion 417 for displaying data output from the remote controller 420.

FIG. 21B1 illustrates a computer, which includes a main body 421, a housing 422, a display portion 423, a keyboard 424, an external connection port 425, a pointing device 426, and the like. Note that this computer is manufactured by using the oxide semiconductor which is a single crystal or substantially equivalent to a single crystal described in any one of Embodiments 1 to 5 or a transistor including the oxide semiconductor. The computer illustrated in FIG. 21B1 may have a structure illustrated in FIG. 21B2. The computer illustrated in FIG. 21B2 is provided with a second display portion 430 instead of the keyboard 424 and the pointing device 426. The second display portion 430 is a touch screen, and input can be performed by operation of display for input on the second display portion 430 with a finger or a dedicated pen. The second display portion 430 can also display images other than the display for input. The display portion 423 may be also a touch screen. Connecting the two screens with a hinge can prevent troubles; for example, the screens can be prevented from being cracked or broken while the computer is being stored or carried. Since the computer includes the oxide semiconductor which is a single crystal or substantially equivalent to a single crystal described in any one of Embodiments 1 to 5 or the transistor including the oxide semiconductor, the computer can be a highly reliable computer.

FIG. 21C illustrates a portable game machine having two housings, a housing 431 and a housing 432, which are connected with a joint portion 433 so that the portable game machine can be opened or folded. The housing 431 and the housing 432 each incorporate the oxide semiconductor which is a single crystal or substantially equivalent to a single crystal described in any one of Embodiments 1 to 5 or a transistor including the oxide semiconductor. The housing 431 incorporates a display portion 434 and the housing 432 incorporates a display portion 435. In addition, the portable game machine illustrated in FIG. 21C includes a speaker portion 436, a recording medium insertion portion 437, an LED lamp 438, an input means (an operation key 439, a connection terminal 440, a sensor 441 (a sensor having a function of measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), and a microphone 442), and the like. The portable game machine illustrated in FIG. 21C has a function of reading out a program or data stored in a storage medium to display it on the display portion, and a function of sharing information with another portable game machine by wireless communication. Note that functions of the portable game machine illustrated in FIG. 21C are not limited to them, and the portable game machine can have a variety of functions. Since the above-described portable game machine incorporating the display portion 434 and the display portion 435 includes the oxide semiconductor which is a single crystal or substantially equivalent to a single crystal described in any one of Embodiments 1 to 5 or the transistor including the oxide semiconductor, the portable game machine can be a highly reliable portable game machine.

FIG. 21D illustrates an example of a mobile phone. The mobile phone illustrated in FIG. 21D is provided with a display portion 452 incorporated in a housing 451, operation buttons 453, an external connection port 454, a speaker 455, a microphone 456, and the like. Note that the mobile phone illustrated in FIG. 21D includes the oxide semiconductor which is a single crystal or substantially equivalent to a single crystal described in any one of Embodiments 1 to 5 or a transistor including the oxide semiconductor. Thus, the mobile phone can be a highly reliable mobile phone.

When the display portion 452 of the mobile phone illustrated in FIG. 21D is touched with a finger or the like, data can be input into the mobile phone. In this case, operations such as making a call and creating an e-mail can be performed by touching the display portion 452 with a finger or the like.

There are mainly three screen modes of the display portion 452. The first mode is a display mode mainly for displaying an image. The second mode is an input mode mainly for inputting information such as characters. The third mode is a display-and-input mode in which two modes of the display mode and the input mode are combined.

For example, in the case of making a call or creating an e-mail, a character input mode mainly for inputting characters is selected for the display portion 452 so that characters displayed on a screen can be input. In this case, it is preferable to display a keyboard or number buttons on almost the entire screen of the display portion 452.

When a detection device including a sensor for detecting inclination, such as a gyroscope or an acceleration sensor, is provided inside the mobile phone, display on the screen of the display portion 452 can be automatically changed by determining the orientation of the mobile phone (whether the mobile phone is placed horizontally or vertically for a landscape mode or a portrait mode).

The screen modes are switched by touch on the display portion 452 or operation with the operation buttons 453 of the housing 451. The screen modes can be switched depending on the kind of images displayed on the display portion 452. For example, when a signal of an image displayed on the display portion is a signal of moving image data, the screen mode is switched to the display mode. When the signal is a signal of text data, the screen mode is switched to the input mode.

Moreover, in the input mode, when input by touching the display portion 452 is not performed for a certain period while a signal detected by an optical sensor in the display portion 452 is detected, the screen mode may be controlled so as to be switched from the input mode to the display mode.

The display portion 452 may function as an image sensor. For example, an image of a palm print, a fingerprint, or the like is taken by touch on the display portion 452 with the palm or the finger, whereby personal authentication can be performed. Further, by providing a backlight or a sensing light source which emits a near-infrared light in the display portion, an image of a finger vein, a palm vein, or the like can be taken.

Note that the structure described in this embodiment can be combined with any of the structures described in Embodiments 1 to 5 as appropriate.

This application is based on Japanese Patent Application serial no. 2013-079300 filed with Japan Patent Office on Apr. 5, 2013, the entire contents of which are hereby incorporated by reference.

What is claimed is:

1. A single-crystal oxide semiconductor comprising:
indium, zinc, and at least one of aluminum, tin, gallium, yttrium, zirconium, lanthanum, cerium, and neodymium,
wherein the single-crystal oxide semiconductor is located over an amorphous surface and has an island shape, an average thickness of less than or equal to 0.5 μm, and an area of 5 μm² or more.

2. The single-crystal oxide semiconductor according to claim 1,
wherein the average thickness is greater than or equal to 5 nm and less than or equal to 0.1 μm and
wherein the area is 1000 μm² or more.

3. The single-crystal oxide semiconductor according to claim 1,
wherein the single-crystal oxide semiconductor is located over a zinc oxide film with a thickness greater than or equal to 0.1 nm and less than or equal to 5 nm and
wherein the zinc oxide film is located over the amorphous surface.

4. A thin film comprising:
a first region and a second region,
wherein the first region is covered by the single-crystal oxide semiconductor according to claim 1, and
wherein the first region has 80% or more of an area of the thin film.

5. A thin film comprising:
a first region and a second region,
wherein the first region is covered by the single-crystal oxide semiconductor according to claim 1, and
wherein the first region has 95% or more of an area of the thin film.

6. An oxide stack comprising:
the single-crystal oxide semiconductor according to claim 1, and a zinc oxide film with a thickness greater than or equal to 0.1 nm and less than or equal to 5 nm.

7. A method for forming an oxide semiconductor, the method comprising:
forming a zinc oxide film over a substrate having an amorphous surface; and
forming the oxide semiconductor over the zinc oxide film by sputtering a polycrystalline oxide semiconductor target including indium, zinc, and at least one of aluminum, tin, gallium, yttrium, zirconium, lanthanum, cerium, and neodymium,
wherein the sputtering is performed under a sputtering gas having a dew point of lower than or equal to −60° C., while heating the substrate at a temperature equal to 200° C. and lower than or equal to 500° C., and
wherein the polycrystalline oxide semiconductor target is c-axis-aligned to a surface thereof which is subjected to the sputtering.

8. The method according to claim 7, wherein the sputtering gas has a dew point of lower than or equal to −100° C.

9. The method according to claim 7, wherein a back surface of the polycrystalline oxide semiconductor target, which opposes to the surface, includes a single-crystal zinc oxide.

10. The method according to claim 7, wherein the zinc oxide film is formed by using the polycrystalline oxide semiconductor target used for forming the oxide semiconductor.
